(19) United States
(12) Patent Application Publication
(10) Pub. No.: US 2007/0269750 A1
(43) Pub. Date: Nov. 22, 2007

(54) Colored masking for forming transparent structures

(75) Inventors: Lyn M. Irving, Rochester, NY (US); David H. Levy, Rochester, NY (US); Mark E. Irving, Rochester, NY (US)

Correspondence Address: Paul A. Leipold;Patent Legal Staff, Eastman Kodak Company, 343 State Street, Rochester, NY, 14650-2201, US

(73) Assignee: Eastman Kodak Company

(21) Appl. No.: 11/437,923

(22) Filed: May 19, 2006

(51) Int. Cl. G03F 7/20

(52) U.S. Cl. 430/322

(57) ABSTRACT

The invention relates to a process for forming a stacked transparent structure comprising providing a support, coating one side of said support with a multicolored mask, coating the other side of the support with a layer curable by visible light, and exposing the light-curable layer through the mask with visible light to cure the layer curable by light in exposed portions to form a cured pattern.

### FIELD OF THE INVENTION

The invention relates to a colored masking technique useful for forming electrical components.

### BACKGROUND OF THE INVENTION

There exist a number of technologies which rely upon accurately patterned sequential layers of electrically and optically active materials applied to a relatively large substrate. Well known applications that might require this include the manufacture of electronic components, flat panel displays, radio frequency identification (RFID) tags, and various sensing applications.

The reasons for patterning accuracy are twofold. First of all, patterned features must be reproduced across large areas of a substrate while having precise control over their dimensions. Secondly, products built with these features typically are composed of several layers of different, but interacting patterned layers, where it is important that the layers be in specific registration. In current practice, the registration is typically achieved using sophisticated equipment that is capable of accepting a support that has a previously patterned layer, and then optically or otherwise detecting the position of the existing pattern so that a new pattern can be applied in registration to the existing pattern. For very precise operations employing rigid glass substrates, even small variations in temperature and humidity cause enough distortion of the existing or new patterns as to cause alignment errors. This requires the use of very sophisticated and expensive equipment to ensure alignment. Furthermore, when nonrigid supports are desired, the amount of dimensional variation with the materials make them extremely difficult to register. U.S. Patent Application 2006/0063351 describes coating the front side and back side of a substrate with one or more resist layers that may be activated simultaneously to impart distinct pattern images within each resist layer. The precoated substrate is inserted between a set of prealigned masks, or alternatively a dual wavelength maskless direct laser writing lithography system is used, to simultaneously expose the front and back sides. There is a growing interest in depositing and patterning thin film semiconductors, dielectrics and conductors on flexible substrates, particularly because these supports would be more mechanically robust, lighter weight, and potentially lead to cheaper manufacturing by allowing roll-to-roll processing. Thus, a situation arises where for some applications, the most desirable and cheapest substrates cannot be used with the materials needed to make the desired devices. The present invention facilitates highly accurate patterning in a simple way, and solves the aforesaid problems.

### PROBLEM TO BE SOLVED BY THE INVENTION

The problems addressed by the current invention are to reproduce patterned features across large areas while having precise control over the feature dimensions and the registration and alignment patterned features that are in different layers. Additionally, it is highly desirable to overcome these problems in a way that does not require expensive equipment or expensive processes.

### SUMMARY OF THE INVENTION

The invention generally is accomplished by a process for forming a stacked transparent structure comprising providing a support, coating one side of said support with a multicolored mask, coating the other side of the support with a layer curable by visible light, and exposing the light-curable layer through the mask with visible light to cure the layer curable by light in exposed portions to form a cured pattern.

### ADVANTAGEOUS EFFECT OF THE INVENTION

The invention provides a method for forming aligned layers without the need for expensive alignment equipment and processes.

### BRIEF DESCRIPTION OF THE DRAWINGS

The above and other objects, features, and advantages of the present invention will become more apparent when taken in conjunction with the following description and drawings wherein identical reference numerals have been used, where possible, to designate identical or analogous features that are common to the figures, and wherein:

FIGS. 1 and 1a. are a pattern of blue color absorber on a transparent support;

FIGS. 2 and 2a. are a pattern of green color absorber on a transparent support;

FIGS. 3 and 3a. are a pattern of red color absorber on a transparent support;

FIGS. 4 and 4a show the individual color absorber layers in a layered structure on support material forming a multicolor mask;

FIGS. 5-6 show a process for selectively forming a pattern of material registered with the blue color absorber pattern of the multicolor mask.

FIGS. 7-8 show a process for selectively forming a pattern of material registered with the green color absorber pattern of the multicolor mask

FIGS. 9-10 show a process for selectively forming a pattern of material registered with the red color absorber pattern of the multicolor mask

FIGS. 11-14 show a process where three different patterned structures are selectively formed by changing the color of exposing light through the multicolor mask.

FIGS. 15-17 show an example of a liftoff patterning process using a multicolor mask;

FIGS. 18-20 show an example of a selective etch patterning process using a multicolor mask.

FIGS. 21-23 show a selective deposition patterning process using a multicolor mask;

FIGS. 24-38 show a possible sequence of exposure, processing, and deposition steps to form a multilayer electronic device using transparent components and a multicolor mask.

### DETAILED DESCRIPTION OF THE INVENTION

### [Definitions]

For ease of understanding, the following terms used herein are described below in more detail:

As utilized herein, the term “back” as applied to the invention article is the side of the support carrying the multicolor mask; the term “front” as used herein refers to the side of the support opposite to the side carrying the mask.

“Vertical” means substantially perpendicular to the surface of a substrate.

“Transparent” generally denotes a material or construct that does not absorb a substantial amount of light in the visible portion (and/or infrared portion in certain variants) of the electromagnetic spectrum. In this invention, the transparency of a materials is only with reference to the colors of light that are being used in a particular process step. Transparent means at least 65% of the reference light passes through the member.

“Positive” refers to a pattern which contains material in those areas above the colored parts of the photomask.

“Negative” refers to a pattern which contains material in those areas above the transparent parts of the photomask.

“Multicolor mask” refers to the vertically aligned set of color absorbing layers in the patterned structure.

A thin film transistor (TFT) is a likely electronic element that can benefit from the patterning process of this invention. The next three definitions refer specifically to thin film transistors.

As used herein, the terms “over,” “above,” and “under” and the like, with respect to layers in the thin film transistor, refer to the order of the layers with respect to the support, but do not necessarily indicate that the layers are immediately adjacent or that there are no intermediate layers.

“Gate” generally refers to the insulated gate terminal of a three terminal FET when used in the context of a transistor circuit configuration.

The preceding term descriptions are provided solely to aid the reader, and should not be construed to have a scope less than that understood by a person of ordinary skill in the art or as limiting the scope of the appended claims.

### [Narrative of the Invention]

The process of this invention can be used to generate any variety of multilayer structures containing patterned layers with fixed vertical registration. This process is therefore capable of producing monolithically integrated structures that can be designed to function as conductors, inductors, capacitors, transistors, diodes, photodiodes, light emitting diodes, and other electronic or optoelectronic components. Furthermore, the patterning technology can be used to simultaneously produce a number of these devices arranged in a way to produce useful electronic circuitry.

The figures and following description illustrate a masking scheme of the current invention. The illustrative example of this description utilizes three masking layers, composed of different color absorbing materials, and utilizes three curable materials, sensitive to colored light, to pattern transparent functional layers.

Light used for exposing can be panchromatic or colored. Panchromatic light refers to light that has a uniform spectral intensity over a given range of wavelengths. For light to be considered panchromatic, the ratio of the minimum intensity to the maximum intensity in a given spectral region should be greater than 60%, preferably greater than 80%. Colored light generally refers to light that has high intensity in certain spectral regions and lower intensities in others. For light to be considered colored, the ratio of the minimum intensity to the maximum intensity across a given spectral region should be less than 20%, preferably less than 10%.

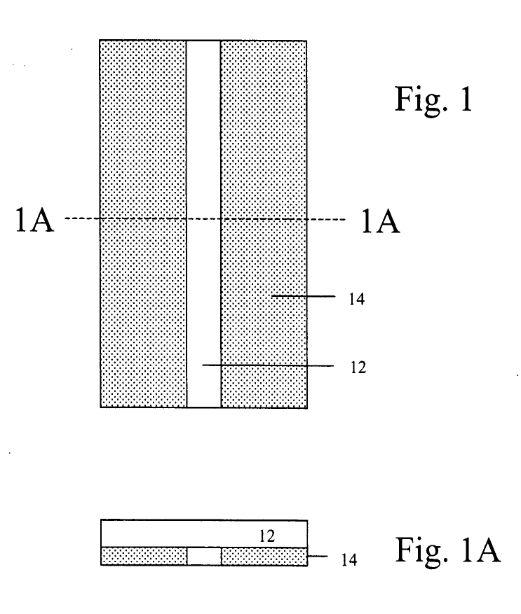

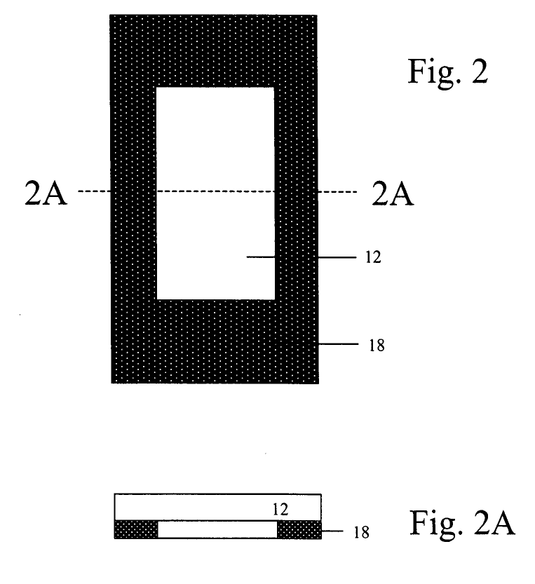

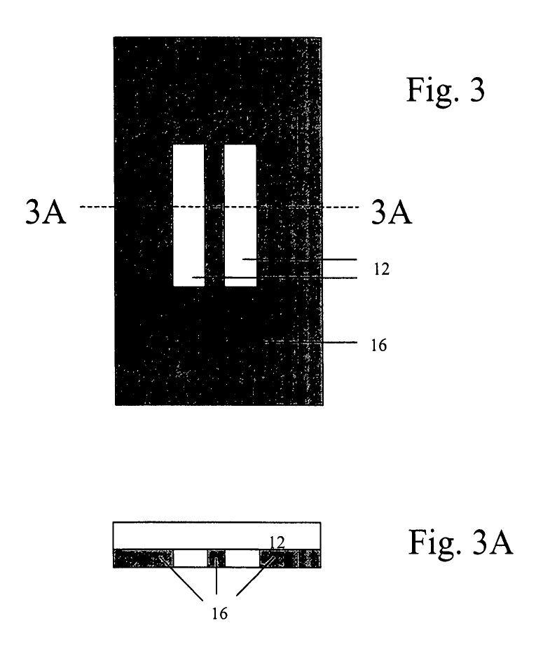

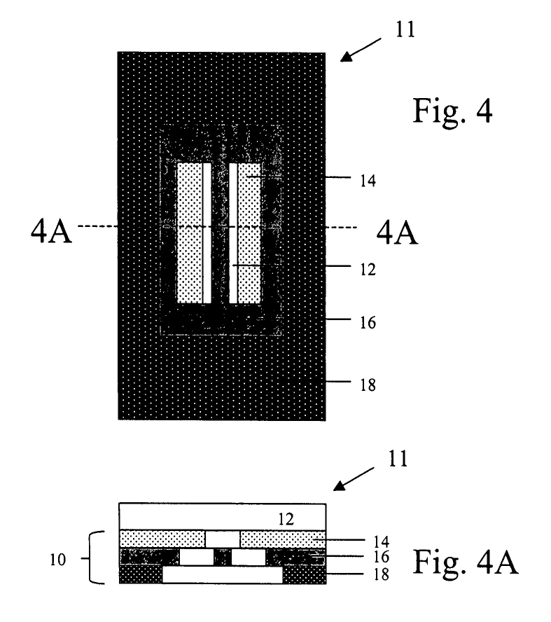

Referring now to the drawings, FIGS. 1, 2 and 3 show the patterns of three mask layers. FIGS. 1 and 1A show the pattern of the first mask layer as a pattern of a blue color absorber (14) on transparent support (12). FIGS. 2 and 2A show the pattern of the second mask layer as a pattern of a green color absorber (18) on transparent support (12). FIGS. 3 and 3A show the pattern of the third mask layer as a pattern of a red color absorber (16) on transparent support (12). FIGS. 4 and 4A show an article 11 composed of individual color absorber layers (14, 16, 18) in a layered structure on support material forming multicolor mask (10). An important aspect of the present invention is that the multicolored mask contains in one structure most or all of the patterning information for the system in a color-encoded form. This is important because the entire article, including support (12) may be exposed to varying temperature, pressure, solvent and humidity treatments during the fabrication and coating steps, naturally leading to variations in dimension (such as shrinkage or thermal expansion) of the support. Web transport systems apply tension to the support, leading to dimensional instability as well. In fact, the lowest cost and potentially cheapest support materials are likely to have a higher degree of dimensional instability. For example, polyester film has a thermal expansion coefficient of 0.0018% per ° C., such that a 5° C. change will result in a dimensional change of 90 μm over 1 meter. The effect of humidity expansion and thermal expansion need not lead to cumulative and catastrophic alignment errors when a multicolor mask element (10) is provided. Simply, the patterning information is contained in the color absorbing layers which are attached to the support, and thus remain in fixed vertical alignment as the support shrinks or expands and are not impacted by support dimensional change.

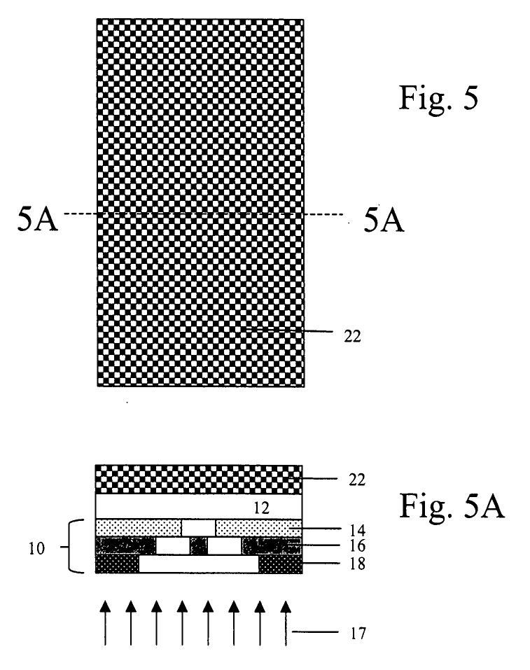

FIGS. 5-10A show processes for selectively forming patterns of curable material registered with a specific color absorber pattern of multicolor mask (10). The specific pattern to be formed is selected by adjusting the sensitivity distribution of the light curable film. A light curable film with a sensitivity to blue, green, or red light is coated on the multicolor mask. This light curable film is exposed with light rays through the multicolor mask. The color absorbers of the multicolor mask selectively transmit the illuminating light, thereby exposing the curable film to a pattern of colored light. For example, a cyan mask absorbs red light while transmitting blue and green light. Similarly, a magenta mask absorbs green light while transmitting red and blue light and a yellow mask absorbs blue light while transmitting red and green light. Thus, by combining the properties of such individual masks, a multicolor mask may be formed to provide patterns of selectively transmitted light. The sensitivity distribution of the light curable film is ideally completely contained within the absorption spectrum of one of the color absorbing materials used in multicolor mask (10) and completely isolated from the absorption spectrum of the other color absorbing materials in multicolor mask (10). In a preferred embodiment of the invention, the light curable film contains a polymerizable compound and a photoinitiator responsive only to specific wavelengths of colored light. Absorption of colored light to which it is sensitive by the photoinitiator initiates the photopolymerization reaction. The light curable coating may contain additional components that include but are not limited to polymeric binders, fillers, pigments, surfactants, adhesion modifiers, antioxidants, coinitiators, chain transfer agents, and the like. One convenient way to modify the sensitivity distribution of the light curable film is with the identity of the photoinitiator. The spectral distribution of illuminating light may be specifically selected to minimize effects from unwanted absorption of the color absorbing material and/or unwanted sensitivity of the light curable material. Following exposure, uncured areas of the light curable material are removed in a development step. This may be accomplished, for example, with a compatible solvent.

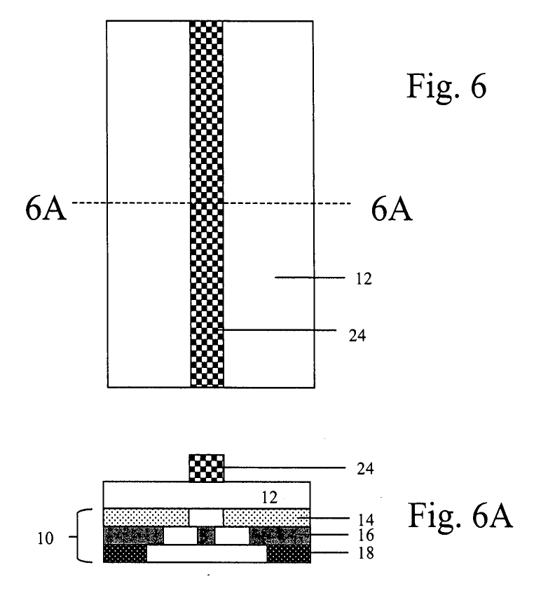

FIGS. 5-6A show a process for selectively forming a pattern of material registered with the blue color absorber pattern of the multicolor mask. Referring now to FIGS. 5 and 5A there is illustrated the multicolor mask (10) which has been coated with a blue curable film (22) and exposed with a light source containing blue light. This light source may be a white light source. FIGS. 6 and 6A show the resulting structure after the exposed blue-curable film from FIG. 5 has been developed, forming a pattern of blue-cured material (24) registered with the blue color absorber pattern (14) of multicolor mask (10).

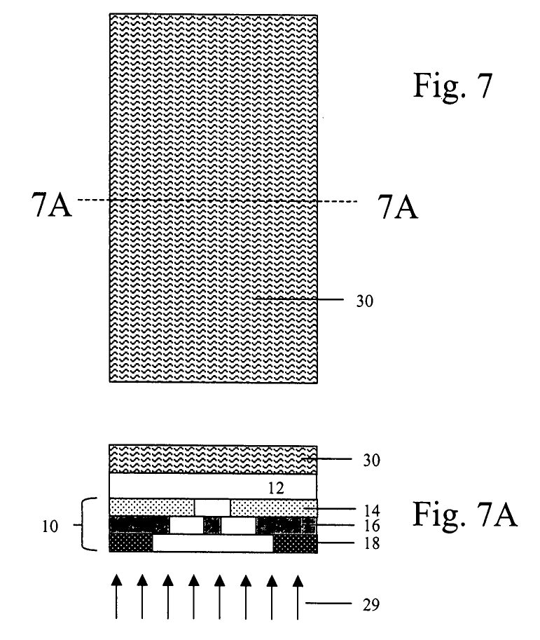

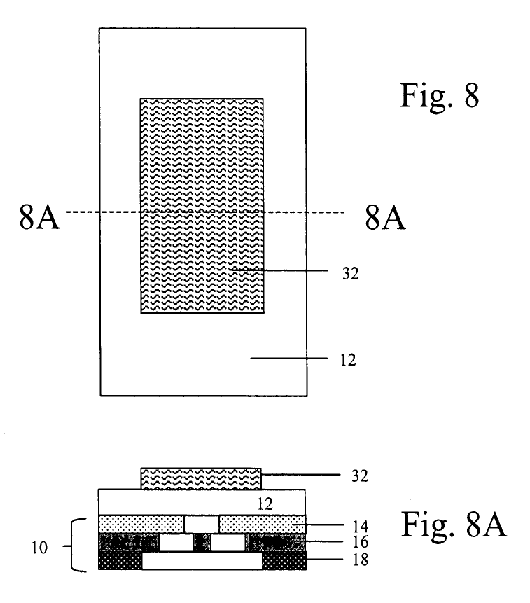

FIGS. 7-8A show a process for selectively forming a pattern of material registered with the green color absorber pattern of the multicolor mask. FIGS. 7 and 7A show the multicolor mask (10) which has been coated with a green curable film (30) and exposed with a light source containing green light. This light source may be a white light source. FIGS. 8 and 8A show the resulting structure after the exposed green-curable film from FIG. 7 has been developed, forming a pattern of green-cured material (32) registered with the green color absorber pattern (18) of multicolor mask (10).

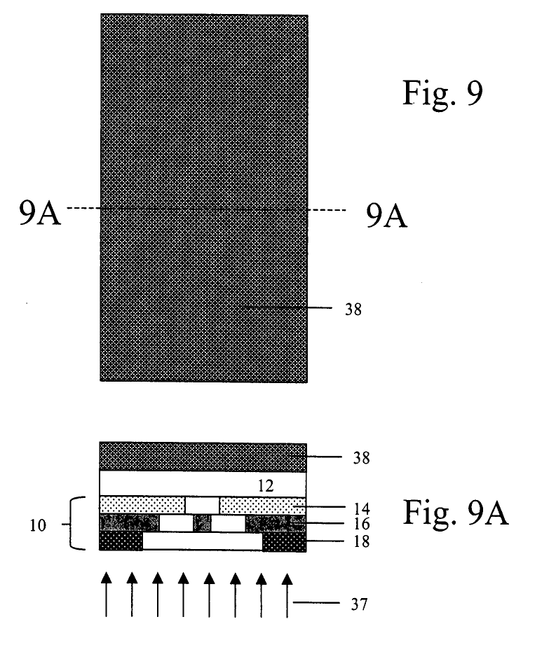

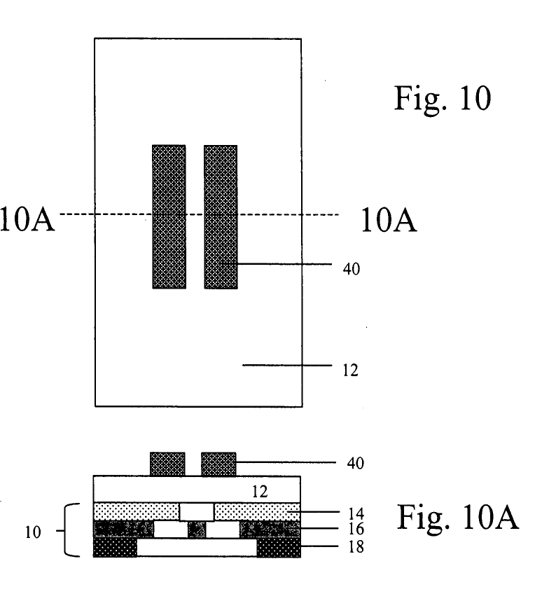

FIGS. 9-10A show a process for selectively forming a pattern of material registered with the red color absorber pattern of the multicolor mask. FIGS. 9 and 9A show the multicolor mask (10) which has been coated with a red curable film (38) and exposed with a light source containing red light. This light source may be a white light source. FIGS. 10 and 10A show the resulting structure after the exposed red-curable film from FIG. 9 has been developed, forming a pattern of red-cured material (40) registered with the red color absorber pattern (16) of multicolor mask (10).

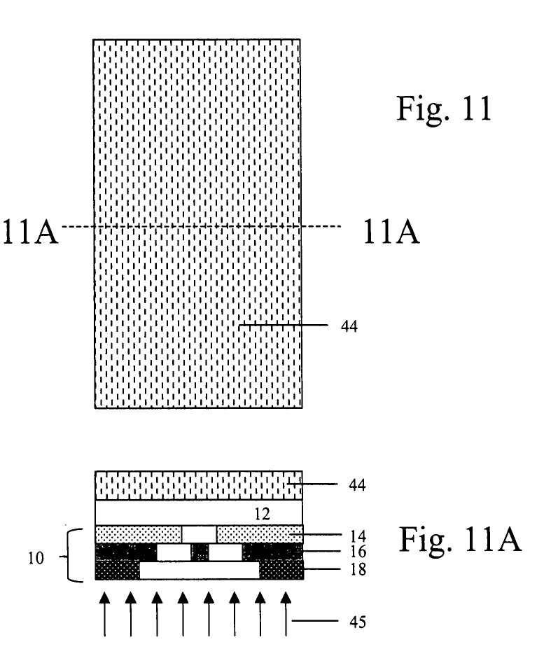

FIGS. 11-14A show a process where three different patterned structures are selectively formed by changing the color of exposing light through the multicolor mask and employing a film 49 curable with panchromatic light. The pan-curable film may be formulated, for example, which contains a polymerizable compound and a mixture of red, green, and blue responsive photoinitiators. When a pan-curable film is used with the present invention, the specific pattern to be formed is selected by adjusting the spectral energy distribution of the exposing light. Therefore, the absorption spectrum of the color absorbing material for the intended pattern should match the wavelength of exposing light. FIGS. 11 and 11A show the multicolor mask (10) which has been coated with a film curable with panchromatic light (44).

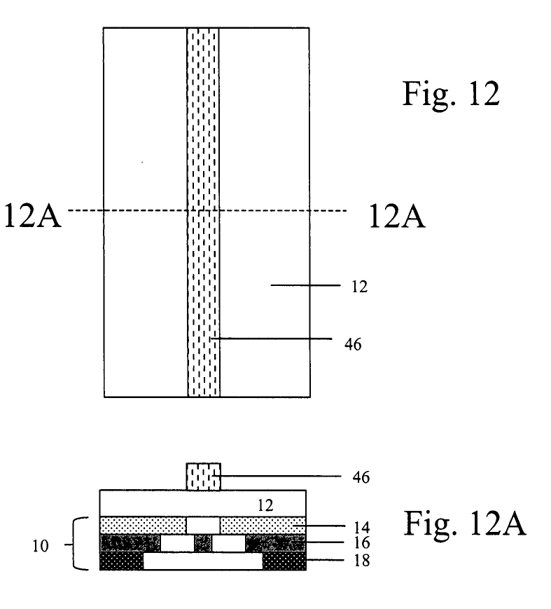

FIGS. 12 and 12A show the resulting structure after the film curable with panchromatic light (44) from FIG. 11 has been exposed with blue light and developed, forming a pattern of cured pan-curable material (46) registered with the blue color absorber pattern (14) of multicolor mask (10).

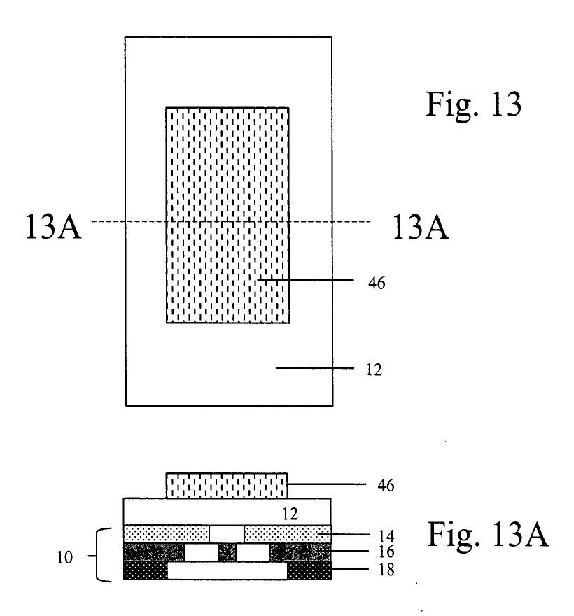

FIGS. 13 and 13A show the resulting structure after the film curable with panchromatic light (44) from FIG. 11 has been exposed with green light and developed, forming a pattern of cured pan-curable material (46) registered with the green color absorber pattern (18) of multicolor mask (10).

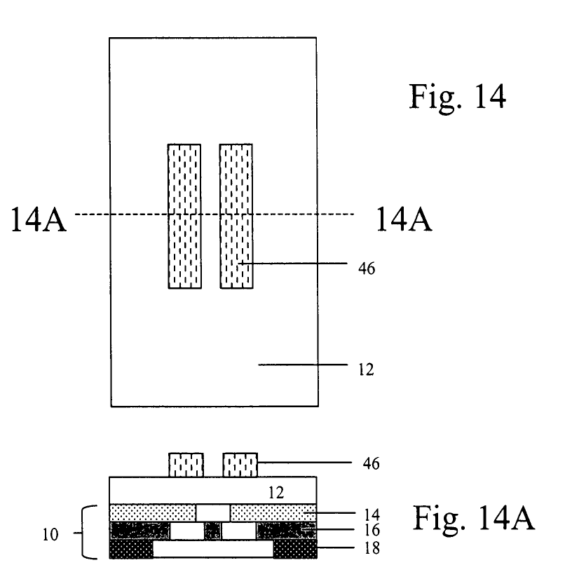

FIGS. 14 and 14A show the resulting structure after the film curable with panchromatic light (44) from FIG. 11 has been exposed with red light and developed, forming a pattern of cured pan-curable material (46) registered with the red color absorber pattern (16) of multicolor mask (10). It will be readily understood that combinations of patterns shown in FIGS. 12-14A are possible simply by tuning the color of exposing light (i.e. a blue+green light exposure will cure both shaded regions shown in FIGS. 12 and 13).

An important aspect of this invention is the ability to use one of the color patterns of the multicolor mask to form an aligned pattern of a functional material on the front side. A number of methods can be used to cause this frontside patterning. Therefore, both functional materials and light curable materials are applied to the multicolor mask and patterned using colored light. General classes of functional materials that can be used include conductors, dielectrics or insulators, and semiconductors. The spectral distribution of illuminating light is modulated by the transmittance of all previously applied and patterned layers. For the purposes of this discussion, the multicolor mask (10) is defined as including all color absorbing portions of the patterned structure with the exception of the light curable film. Because the colored light curing process described above and illustrated using FIGS. 5-14 results in a change in permeability, solubility, tackiness, mechanical strength, surface reactivity, and index of refraction of the cured material, these properties may be exploited in subsequent fabrication steps. Particularly useful methods to pattern functional and electronic materials using this invention are referred to as liftoff, selective etch, and selective deposition processes.

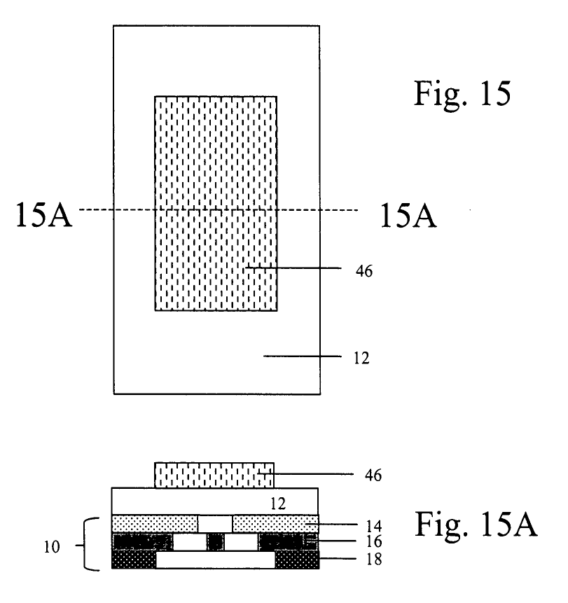

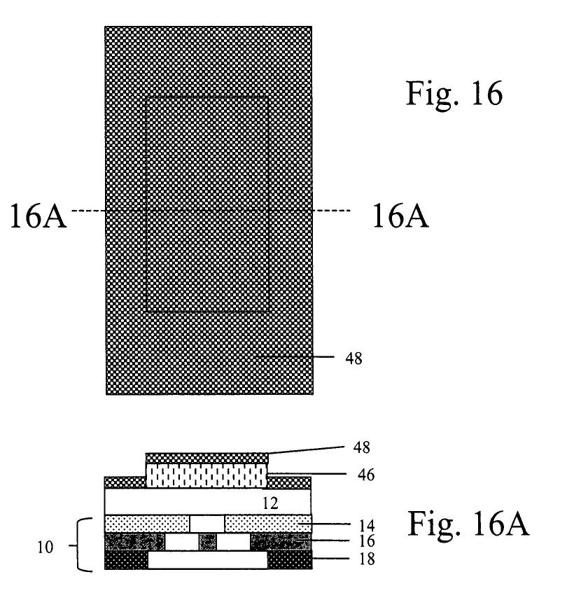

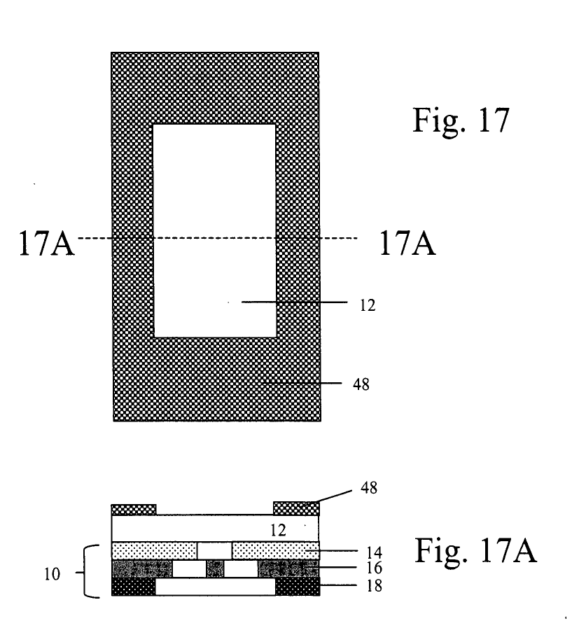

FIGS. 15-17A shows the operation of this system using a liftoff patterning process. FIGS. 15 and 15A show multicolor mask (10) with a pattern of cured material (46) registered with green color absorber pattern (18). Referring now to FIGS. 16 and 16A, a uniform coating of transparent functional material (48) is applied over the pattern of cured material (46). FIGS. 17 and 17A show the final step in a liftoff sequence when the cured material (46) and portions of transparent functional material on top of the cured material are removed. This is accomplished, for example, by treating the sample with a material that selectively attacks the remaining cured material under the functional material. This leaves functional material where there was originally no light cured material.

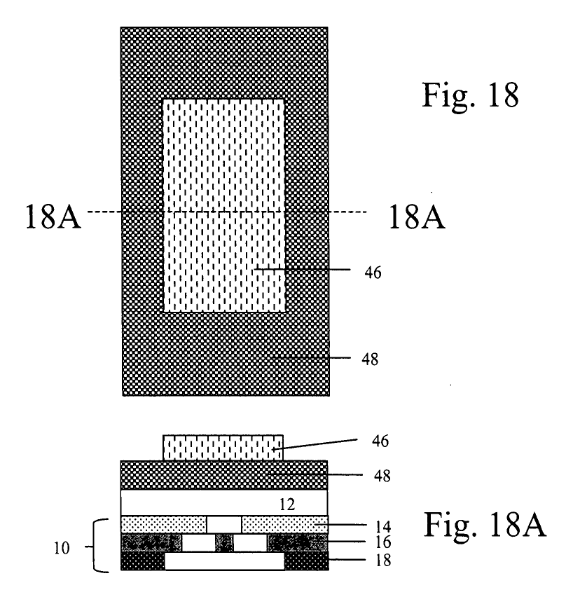

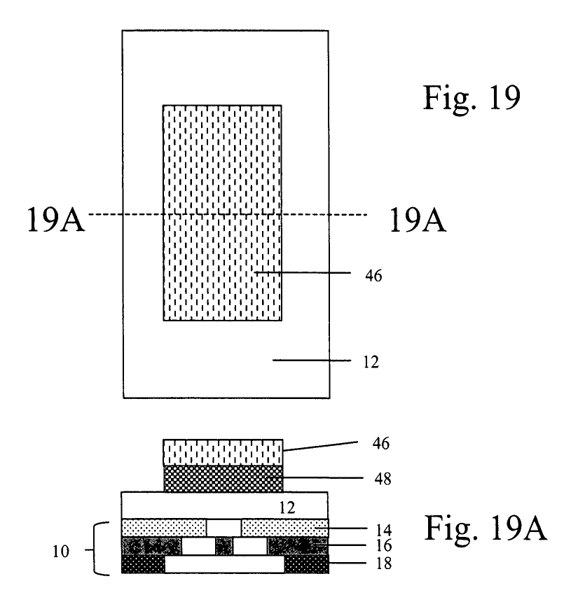

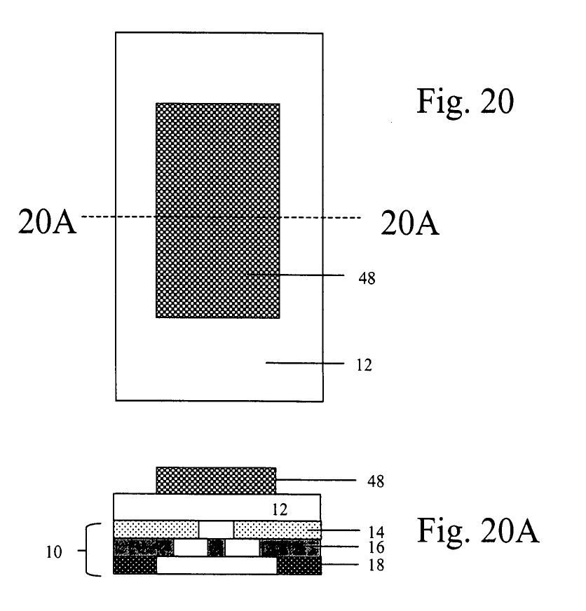

FIGS. 18-20 shows the operation of this system using a selective etch patterning process. FIGS. 18 and 18A show multicolor mask (10) with a uniform coating of transparent functional material (48) under a pattern of cured material (46) registered with green color absorber pattern (18). FIGS. 19 and 19A illustrate a subsequent step after the exposed portions of transparent functional material are removed in an etch process. The sample is exposed to a material that attacks or dissolves the functional layer. Regions of transparent functional material protected by the pattern of cured material (46) are not removed in the etch step. The pattern of transparent functional material (48) is registered with the pattern of cured material (46) and is also registered with green color absorber pattern (18). Referring now to FIGS. 20 and 20A there is illustrated the resulting structure after the pattern of cured material (46) is removed. This may be accomplished, for example, with a compatible solvent or oxygen plasma treatment.

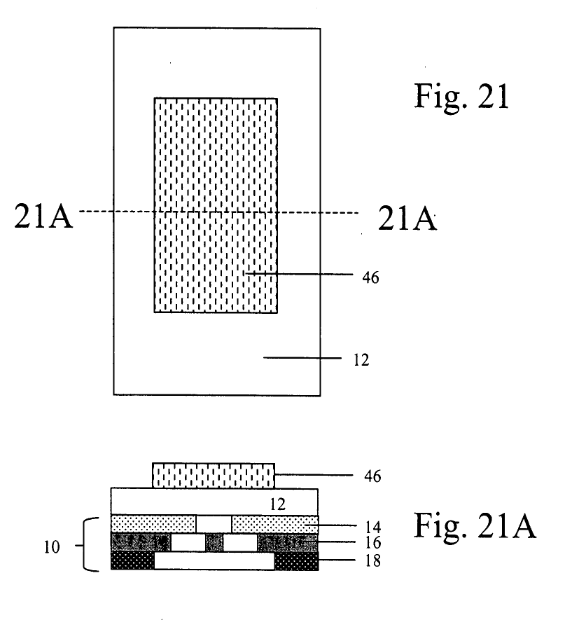

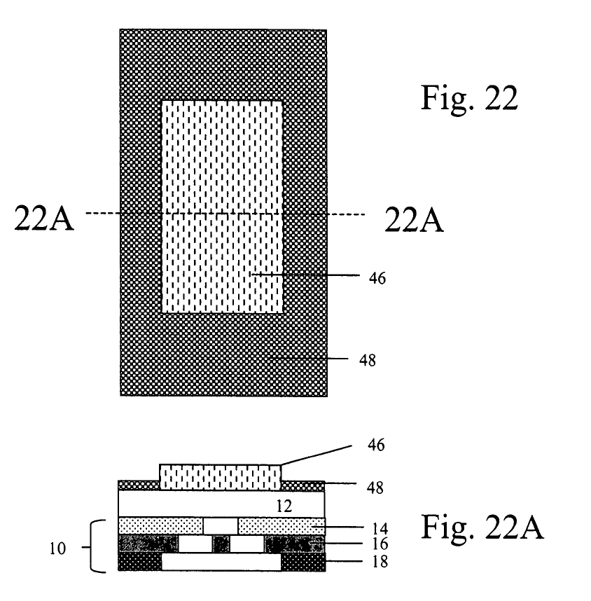

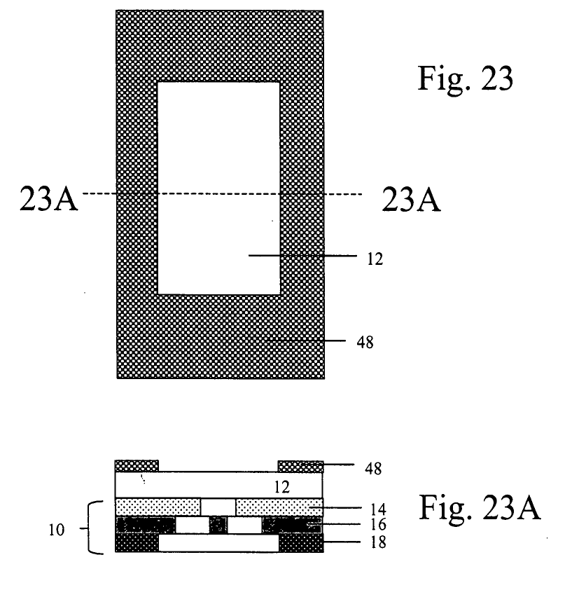

FIGS. 21-23A shows the operation of this system using a selective deposition patterning process. A number of deposition processes employing both liquids and vapor phase chemical delivery can be tailored to operate in a manner where material selectively deposits only in certain areas. For example, FIGS. 21 and 21A show multicolor mask (10) with a pattern of cured material (46) registered with green color absorber pattern (18). FIGS. 22 and 22A illustrate a subsequent step after a transparent functional material (48) is selectively deposited on regions of support (12) which are not covered by the pattern of cured material (46). Referring now to FIGS. 23 and 23A a subsequent step is illustrated where the pattern of cured material (46) is removed by treating entire to attack the remaining cured material. The pattern of transparent functional material (48) is registered with the green color absorber pattern (18).

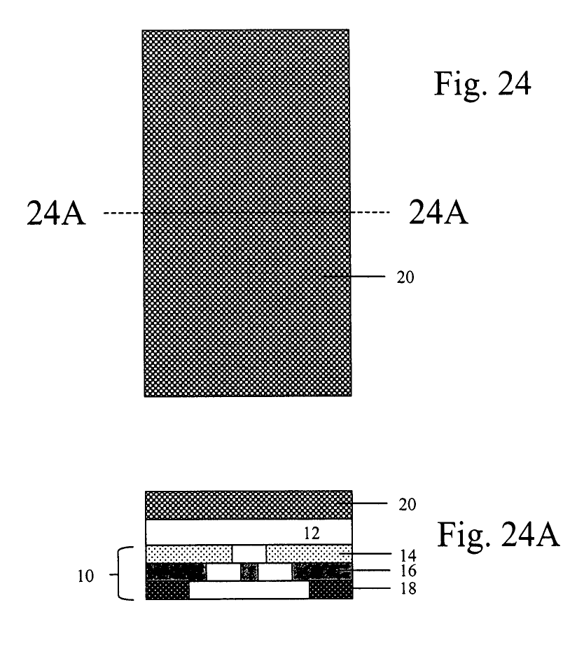

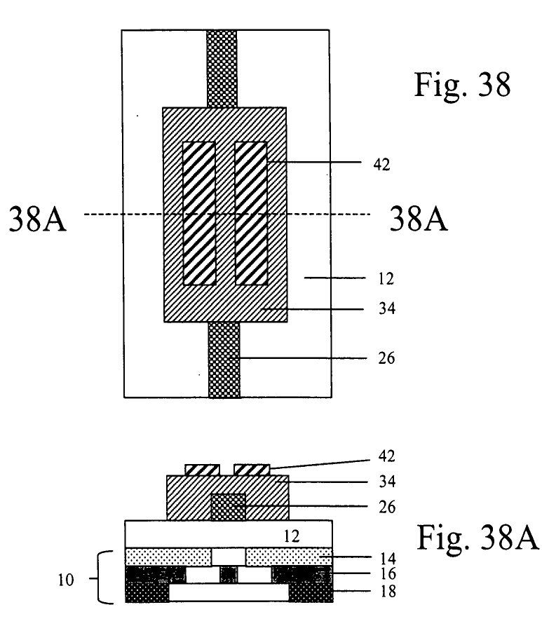

FIGS. 24-38A show a possible sequence of exposure, processing, and deposition steps that would allow construction of a multilayer electronic device as seen in FIGS. 38 and 38A.

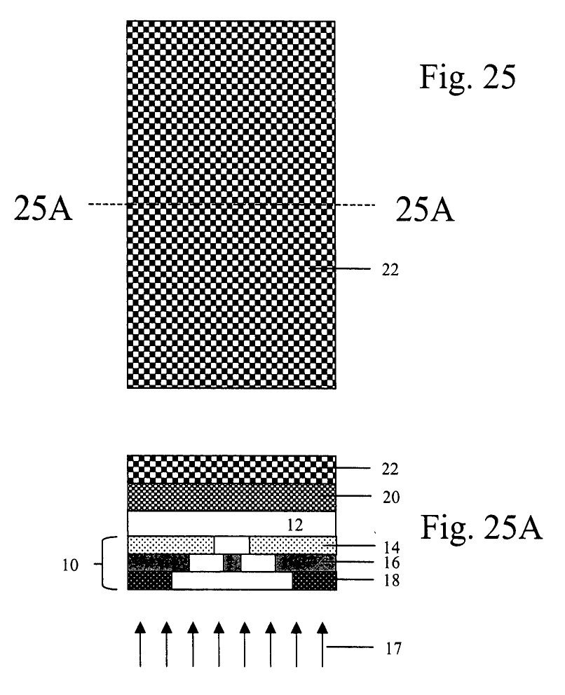

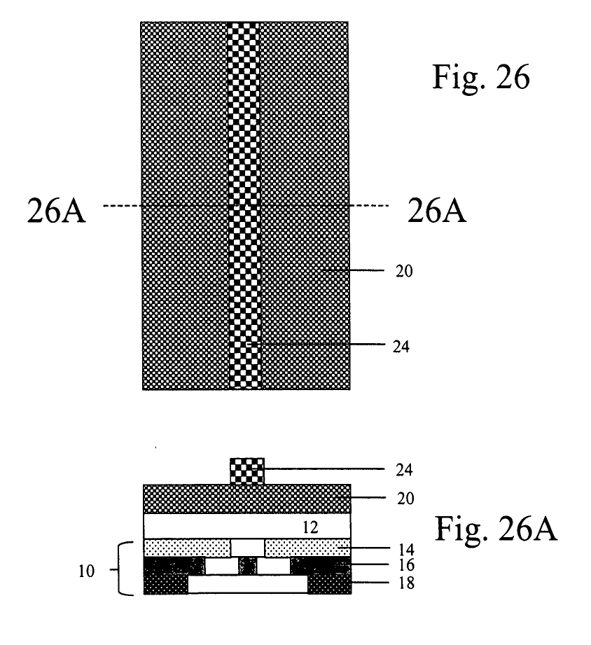

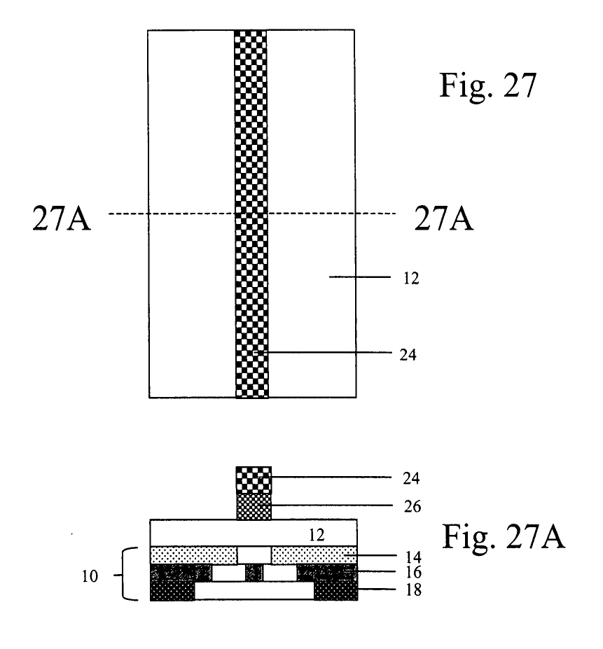

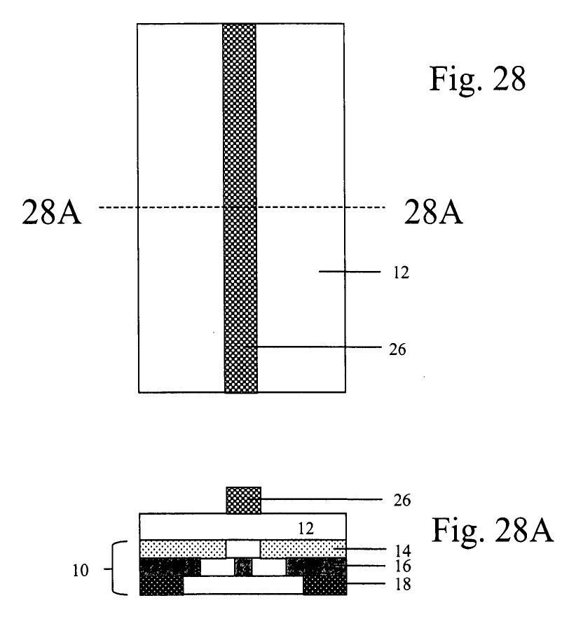

FIGS. 24-28A illustrate the coating and patterning steps for the first transparent layer of the electronic device using a blue curable coating and a selective etch process. FIGS. 24 and 24A shows multicolor mask (10) coated with a first transparent functional material (20). By way of illustration, the functional material (20) could be a transparent conducting oxide material such as ITO or aluminum doped ZnO. Referring now to FIGS. 25 and 25A there is illustrated a subsequent step. A blue-curable material (22) is applied over the previous structure and exposed with a light source containing blue light. Because the curable coating drawn in this structure is sensitive only to blue light, the light source may be a white light source, or a colored light source containing blue light. Referring now to FIGS. 26 and 26A there is illustrated the resulting structure after the exposed blue-curable film has been developed, forming a pattern of blue-cured material (24) registered with the blue color absorber pattern (14) of multicolor mask (10). FIGS. 27 and 27A show an etch step where exposed portions of transparent functional material (20) are removed in, for example, an acid bath, forming a pattern of transparent functional material (26) registered to the blue color absorber pattern (14) of multicolor mask (10). FIGS. 28 and 28A show the structure of FIG. 27 after the pattern of blue cured material (24) is removed using, for example, an oxygen plasma treatment.

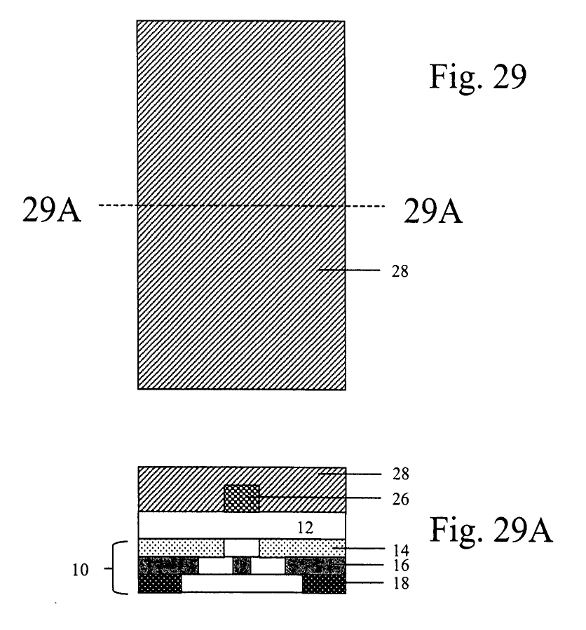

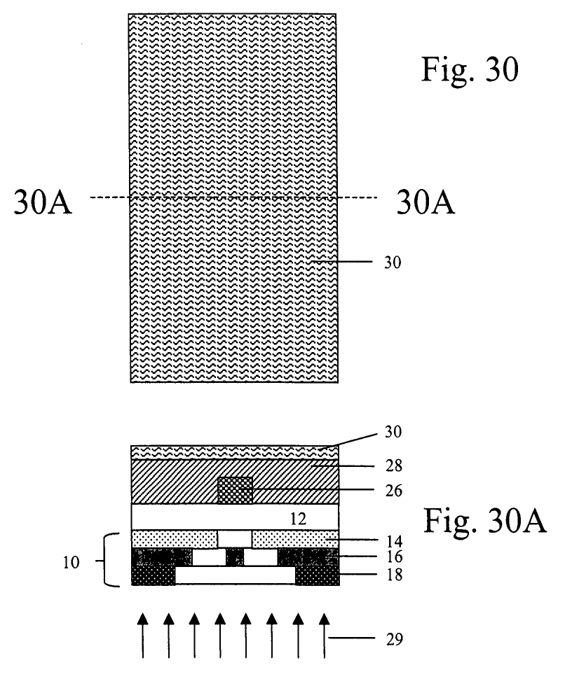

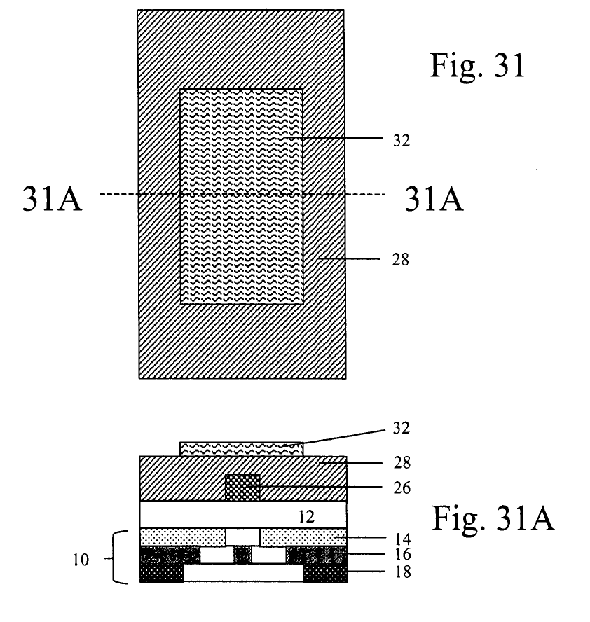

FIGS. 29-33A illustrate the coating and patterning steps for the second transparent layer of the electronic device using a green curable coating using a selective etch process. Alternatively, the second transparent layer could be patterned be a selective deposition process, a liftoff process, or a light curing process. FIGS. 29 and 29A show the multicolor mask (10), including the first patterned transparent layer, coated with a uniform layer of transparent functional material (28). By way of example, this material could be a dielectric material such as aluminum oxide or alternatively a semiconducting layer such as zinc oxide. This material could be a dielectric or semiconducting layer precursor which is converted in an annealing step to form the electrically functional material. Multiple layers of transparent functional layers could potentially be coated at this step. By way of example, a transparent coating of a dielectric material could be first applied and a second transparent coating of semiconductor material could be subsequently applied. Referring now to FIGS. 30 and 30A there is illustrated a subsequent step. A green-curable material (30) is applied over the previous structure drawn in FIG. 29 and exposed with a light source containing green light. Because the curable coating drawn in this structure is sensitive only to green light, the light source may be a white light source, or a colored light source containing green light. FIGS. 31 and 31A show the resulting structure after the exposed green-curable material (30) from FIG. 30 has been developed, forming a pattern of green-cured material (32) registered with the green color absorber pattern (18) of multicolor mask (10).

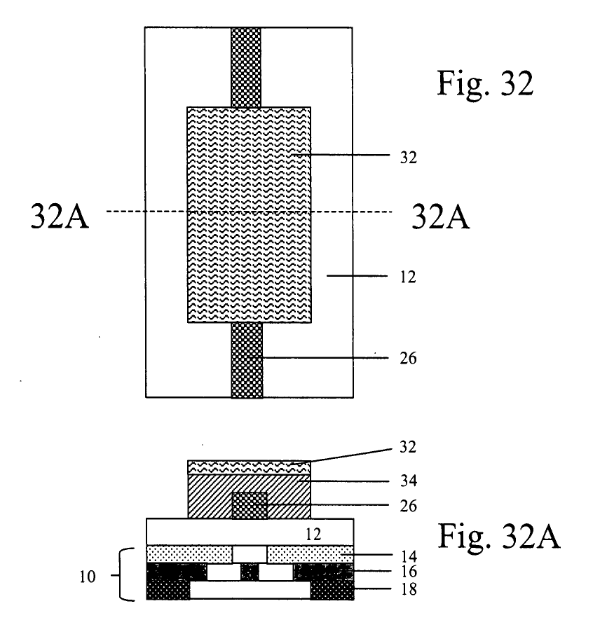

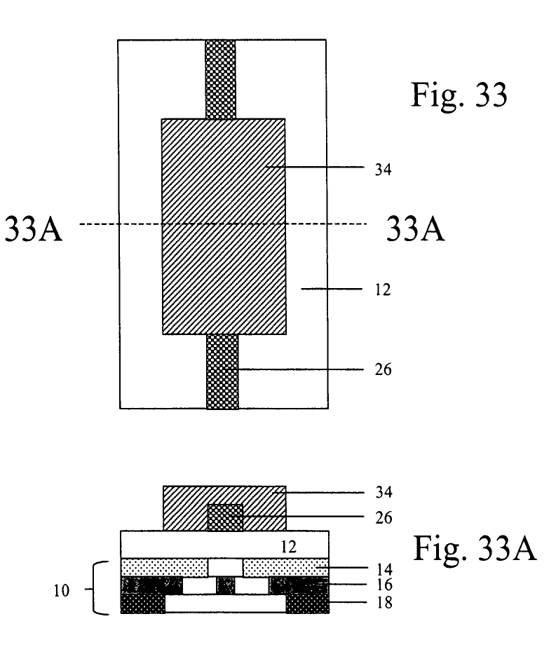

Referring now to FIGS. 32 and 32A there is illustrated the structure of FIG. 31 after the exposed portions of transparent functional material (28) are removed in an etch step, forming a pattern of transparent functional material (34) registered to the green color absorber pattern (18) of multicolor mask (10). FIGS. 33 and 33A show the structure of FIG. 32 after the pattern of green cured material (32) is removed using, for example, an oxygen plasma treatment.

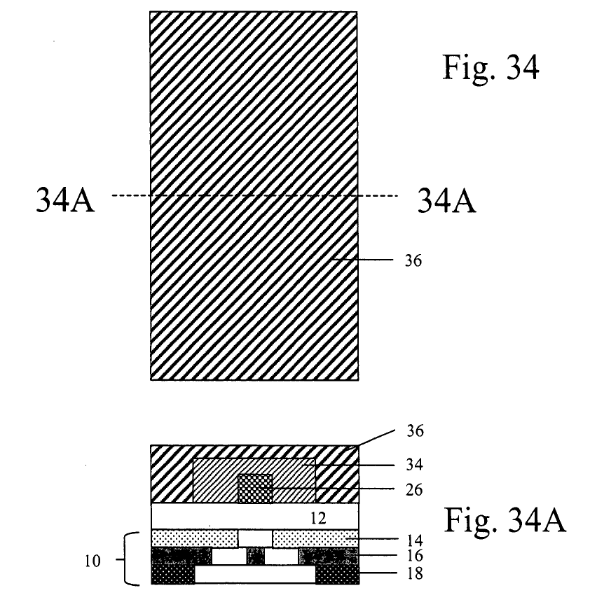

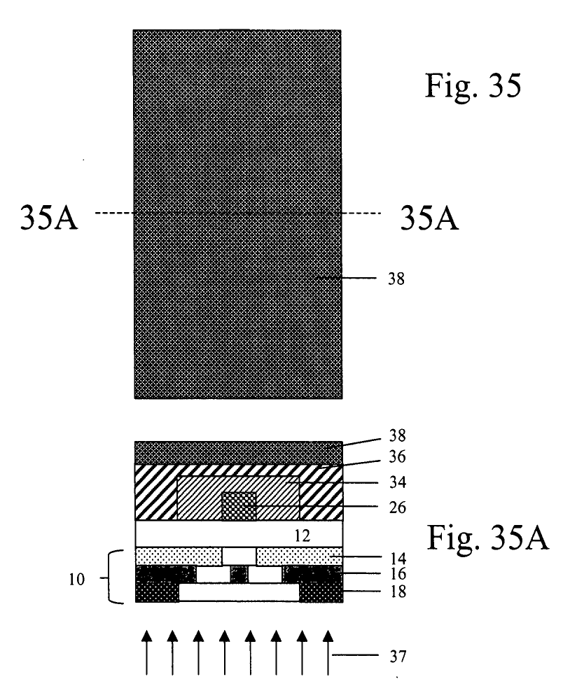

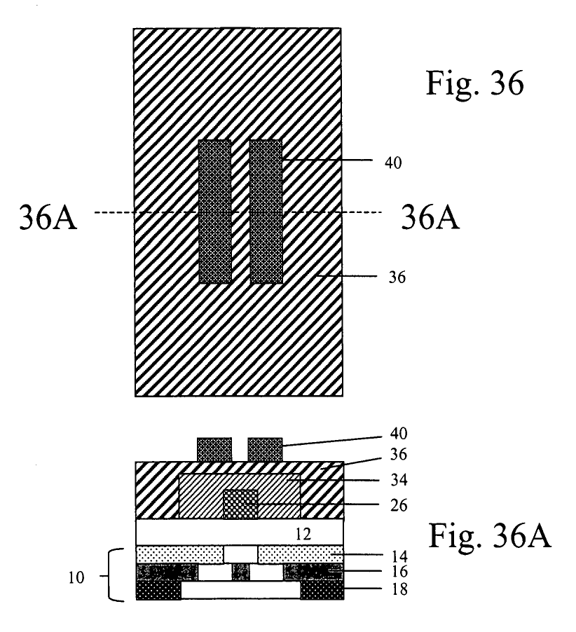

FIGS. 34-38A illustrate the coating and patterning steps for the third transparent layer of the electronic device using a red curable coating using a selective etch process. Alternatively, the third layer could be patterned be a selective deposition process, a liftoff process, or a light curing process. FIGS. 34 and 34A show the multicolor mask (10), including the first and second patterned transparent layers, coated with a uniform layer of transparent functional material (36). By way of example, this could be a layer of silver nanoparticles. Referring now to FIGS. 35 and 35A there is illustrated a subsequent step. A red-curable material (38) is applied over the previous structure drawn in FIGS. 34 and 34A and exposed with a light source containing red light. Because the curable coating drawn in this structure is sensitive only to red light, the light source may be a white light source, or a colored light source containing red light. FIGS. 36 and 36A show the resulting structure after the exposed red-curable material (38) from FIG. 35 has been developed, forming a pattern of red-cured material (40) registered with the red color absorber pattern (16) of multicolor mask (10).

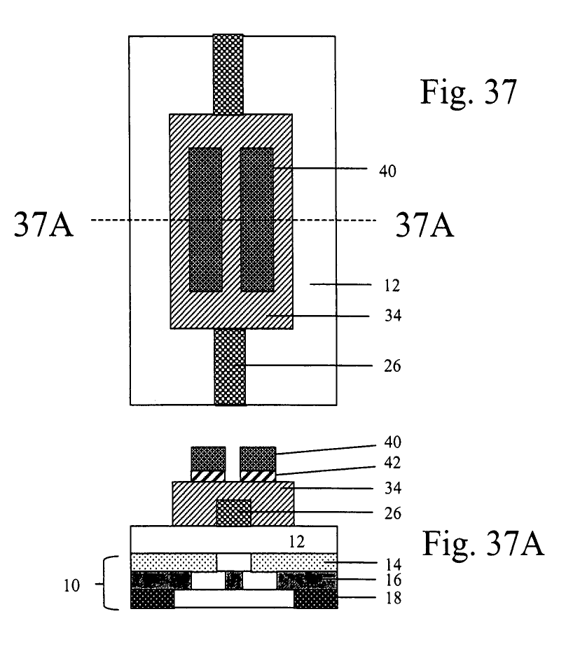

Referring now to FIGS. 37 and 37A there is illustrated the structure of FIG. 36 after the exposed portions of transparent functional material (36) are removed in an etch step, forming a pattern of transparent functional material (42) registered to the red color absorber pattern (16) of multicolor mask (10). FIGS. 38 and 38A show the structure of FIG. 37 after the pattern of red cured material (40) is removed. In this multilayer structure, the pattern of transparent functional material (26) is registered to the blue color absorber pattern (14) of multicolor mask (10). The pattern of transparent functional material (34) is registered to the green color absorber pattern (18) of multicolor mask (10). The pattern of transparent functional material (42) is registered to the red color absorber pattern (16) of multicolor mask (10).

### [Mask Generation]

An important aspect of the present invention is the multicolored mask which contains in one structure most or all of the patterning information for the system. This multicolor mask can be generated by any method that produces an image containing the desired colors with sufficient precision and registration for the anticipated application.

The different color absorbers in the multicolored mask may be sequentially or simultaneously deposited and patterned by many methods. One method to produce the multicolor mask is to print the mask using inks containing dyes or pigments with the appropriate spectral qualities. Inks used in the printing could be of any common formulation, which would typically include the colorant material along with a vehicle or solvent, binders, and surfactants. Examples of such multicolor printing systems are inkjet printing, gravure printing, flexography, offset lithography, screen or stencil printing, and relief printing. Color thermographic printing may be used to produce the different color absorbing layers on the support. Thermochromic compounds, bleachable dyes, heat decomposable compounds, or chemical color formers may be used to form the different color absorbing layer patterns on the support. The different color absorbers may be applied to the support using a laser or thermal transfer process from a donor sheet. Alternately, the color absorbing patterns may be produced on the support by an ablative recording process.

Particularly useful color absorbers are those materials with maximum absorption in a selected portion of the visible band and maximum transmission in remaining portions. So-called block-type dyes and cutoff filter materials are ideal for use in the multicolor mask. The different color absorbers may be applied in any convenient order, or applied in a single layer dispersed in a binder. A receiving layer for color absorbing materials may optionally be coated on the back side of the support before the color absorbing materials are applied.

The different color absorbers in the multicolor mask may be formed by a photolithographic method using, for example, dyed photocurable coatings, such as pigmented or dyed photoresist.

It may be particularly convenient and cost effective to produce a reusable master image for subsequent duplication on the main substrate. In this embodiment, a master mask image is produced of very high accuracy and resolution. This may be accomplished with any of the above techniques. Preferably, this would be done with a photolithographic method that allows a very high quality master image to be produced. It may even be preferable to produce the master image upon a rigid transparent substrate in order to achieve highly accurate vertical alignment between color absorbing layers. The color information in the master color image can be reproduced on the main substrate using a color duplicating or color copying process. For negative-working duplication processes, the master color image would be provided as a negative copy of the multicolor mask.

In a traditional photolithographic process for large area electronic device fabrication, excellent alignment must be achieved over very large areas. In the above method of master duplication, the master may be considerably smaller and thus easier to fabricate, but then duplicated on the final substrate in a replicating pattern so as to cover a larger area. Although this method of stepping is used for individual mask layers in a conventional photolithographic process, in those processes excellent alignment is still required within the stepping operation. In the current inventive process, considerable tolerance can exist in the location of the individual duplications, since each will contain all the required information for a multilayer pattern.

Color image capture processes employing light sensitive materials may be used to reproduce the master color image. The light sensitive layers can be composed of any set of materials capable of capturing a multicolor light pattern and subsequently being treated or developed in a way to produce a color pattern. Examples of such multicolor image capture materials are color negative photographic imaging layers, color reversal photographic imaging layers, color photothermographic imaging layers, Cycolor imaging layers, and diffusion transfer color photographic imaging layers such as color instant films, and color Pictrography film. A master color image may alternatively be reproduced on the main substrate using a color duplicating or copying process such as color electrophotography.

The multicolor mask can be produced on a separate roll of material and then laminated to the back side of the substrate. Preferably the lamination is done with the image side of the mask close to the substrate and using a thin adhesion system so that the mask image is as close as possible to the top side of the substrate on which will be the active devices.

It may be particularly advantageous for optical considerations to coat the main support layer directly onto the color absorbing layers of the multicolor mask. In this embodiment, the color absorbing layers could be patterned on a carrier support roll and then the main support layer could be cast directly onto the color absorbing layers. In this fashion, the mask image is as close as possible to the top side of the substrate on which will be the active devices.

Alternately, the color absorbing layers can be patterned on a separate (donor) roll of material and then all of the color absorbing layers can be transferred in a single step from the donor roll onto the main substrate.

### [Light Curable Polymer Layer]

Many polymers can be caused to vary their properties by exposure to light, and thus be useful as light curable layers. Many typical light sensitive polymers are only sensitive to UV and deep UV radiation. Preferably the curable materials for this invention are rendered sensitive to visible light.

A variety of photopolymerization systems that are activated by visible radiation have been developed. A useful discussion of UV curable and visible light curable materials can be found in “Photoreactive Polymers: The Science and Technology of Resists” by A. Reiser, Wiley-Interscience, John Wiley & Sons, 1989, pp. 102-129. Farid U.S. Pat. No. 4,859,572, incorporated here by reference, describes a photographic imaging system which relies on using visible light to harden an organic component and produce an image pattern. This reference describes a variety of suitable visible light sensitive photoinitiators, monomers, and film formulation guidelines for use in the curable layers of this invention.

Sensitivity to visible light can be accomplished by the use of polymerizable compound along with a photopolymerization initiator. In a preferred embodiment of the invention, the photosensitive resist contains a polymerizable compound selected from among compounds having at least one, preferably two or more, ethylenically unsaturated bond at terminals. Such compounds are well known in the industry and they can be used in the present invention with no particular limitation. Such compounds have, for example, the chemical form of a monomer, a prepolymer, i.e., a dimer, a trimer, and an oligomer or a mixture and a copolymer of them. As examples of monomers and copolymers thereof, unsaturated carboxylic acids (e.g., acrylic acid, methacrylic acid, itaconic acid; crotonic acid, isocrotonic acid, maleic acid, etc.), and esters and amides thereof can be exemplified, and preferably esters of unsaturated carboxylic acids and aliphatic polyhydric alcohol compounds, and amides of unsaturated carboxylic acids and aliphatic polyhydric amine compounds are used. In addition, the addition reaction products of unsaturated carboxylic esters and amides having a nucleophilic substituent such as a hydroxyl group, an amino group and a mercapto group with monofunctional or polyfunctional isocyanates and epoxies, and the dehydration condensation reaction products of these compounds with monofunctional or polyfunctional carboxylic acids are also preferably used. The addition reaction products of unsaturated carboxylic esters and amides having electrophilic substituents such as an isocyanato group and an epoxy group with monofunctional or polyfunctional alcohols, amines and thiols, and the substitution reaction products of unsaturated carboxylic esters and amides having releasable substituents such as a halogen group and a tosyloxy group with monofunctional or polyfunctional alcohols, amines and thiols are also preferably used. As another example, it is also possible to use compounds replaced with unsaturated phosphonic acid, styrene, vinyl ether, etc., in place of the above-unsaturated carboxylic acids.

Specific examples of ester monomers of aliphatic polyhydric alcohol compounds and unsaturated carboxylic acids include, as acrylates, ethylene glycol diacrylate, triethylene glycol diacrylate, 1,3-butanediol diacrylate, tetramethylene glycol diacrylate, propylene glycol diacrylate, neopentyl glycol diacrylate, trimethylolpropane triacrylate, trimethylolpropane tri(acryloyloxypropyl)ether, trimethylolethane triacrylate, hexanediol diacrylate, 1,4-cyclohexanediol diacrylate, tetraethylene glycol diacrylate, pentaerythritol diacrylate, pentaerythritol triacrylate, pentaerythritol tetraacrylate, dipentaerythritol diacrylate, dipentaerythritol hexaacrylate, sorbitol triacrylate, sorbitol tetraacrylate, sorbitol pentaacrylate, sorbitol hexaacrylate, tri(acryloyloxyethyl) isocyanurate, polyester acrylate oligomer, etc. As methacrylates, examples include tetramethylene glycol dimethacrylate, triethylene glycol dimethacrylate, neopentyl glycol dimethacrylate, trimethylolpropane trimethacrylate, trimethylolethane trimethacrylate, ethylene glycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol hexamethacrylate, sorbitol trimethacrylate, sorbitol tetramethacrylate, and bis[p-(3-methacryloxy-2-hydroxy-propoxy)phenyl]dimethylmethane, bis[p-(methacryloxyethoxy)-phenyl]dimethylmethane. As itaconates, examples include ethylene glycol diitaconate, propylene glycol diitaconate, 1,3-butanediol diitaconate, 1,4-butanediol diitaconate, tetramethylene glycol diitaconate, pentaerythritol diitaconate, and sorbitol tetraitaconate. As crotonates, examples include ethylene glycol dicrotonate, tetramethylene glycol dicrotonate, pentaerythritol dicrotonate, and sorbitol tetradicrotonate. As isocrotonates, examples include ethylene glycol diisocrotonate, pentaerythritol diisocrotonate, and sorbitol tetraisocrotonate. As maleates, examples include ethylene glycol dimaleate, triethylene glycol dimaleate, pentaerythritol dimaleate, and sorbitol tetramaleate. Further, the mixtures of the above-described ester monomers can also be used. Further, specific examples of amide monomers of aliphatic polyhydric amine compounds and unsaturated carboxylic acids include methylenebis acrylamide, methylenebis-methacrylamide, 1,6-hexamethylenebis-acrylamide, 1,6-hexamethylenebis-methacrylamide, diethylenetriaminetris-acrylamide, xylylenebis-acrylamide, and xylylenebis-methacrylamide.

Further, urethane-based addition polymerizable compounds which are obtained by the addition reaction of an isocyanate and a hydroxyl group are also preferably used in the present invention. A specific example is a vinyl urethane compound having two or more polymerizable vinyl groups in one molecule, which is obtained by the addition of a vinyl monomer having a hydroxyl group represented by the following formula (V) to a polyisocyanate compound having two or more isocyanate groups in one molecule.

CH₂═C(R)COOCH₂CH(R′)OH

wherein R and R′ each represents H or CH 3.

Other examples include polyfunctional acrylates and methacrylates, such as polyester acrylates, and epoxy acrylates obtained by reacting epoxy resins with (meth)acrylic acids. Moreover, photo-curable monomers and oligomers listed in Sartomer Product Catalog by Sartomer Company Inc. (1999) can be used as well.

Depending upon the final design characteristics of the photosensitive material, a suitable addition polymerizable compound or combination of addition polymerizable compounds, having the desired structure and amounts can be used. For example, the conditions are selected from the following viewpoint. For the photosensitive speed, a structure containing many unsaturated groups per molecule is preferred and in many cases bifunctional or more functional groups are preferred. For increasing the strength of an image part, i.e., a cured film, trifunctional or more functional groups are preferred. It is effective to use different functional numbers and different polymerizable groups (e.g., acrylate, methacrylate, styrene compounds, vinyl ether compounds) in combination to control both photosensitivity and strength. Compounds having a large molecular weight or compounds having high hydrophobicity are excellent in photosensitive speed and film strength, but may not be preferred from the point of development speed and precipitation in a developing solution. The selection and usage of the addition polymerizable compound are important factors for compatibility with other components (e.g., a binder polymer, an initiator, a functional materialetc.) in the photopolymerization composition For example, sometimes compatibility can be improved by using a low purity compound or two or more compounds in combination. Further, it is also possible to select a compound having specific structure for the purpose of improving the adhesion property of a support, a functional material, and an overcoat layer. Concerning the compounding ratio of the addition polymerizable compound in a photopolymerization composition, the higher the amount, the higher the sensitivity. But, too large an amount sometimes results in disadvantageous phase separation, problems in the manufacturing process due to the stickiness of the photopolymerization composition (e.g., manufacturing failure resulting from the transfer and adhesion of the photosensitive material components), and precipitation from a developing solution. The addition polymerizable compound may be used alone or in combination of two or more. In addition, appropriate structure, compounding ratio and addition amount of the addition polymerizable compound can be arbitrarily selected taking into consideration the degree of polymerization hindrance due to oxygen, resolving power, fogging characteristic, refractive index variation and surface adhesion. Further, the layer constitution and the coating method of undercoating and overcoating can be performed according to circumstances.

Organic polymeric binders which can form a part of the film forming component of the light curable layer include: (1) polyesters, including those based on terephthalic, isophthalic, sebacic, adipic, and hexahydroterephthalic acids; (2) nylons or polyamides; (3) cellulose ethers and esters; (4) polyaldehydes; (5) high molecular weight ethylene oxide polymers—e.g., poly(ethylene glycols), having average weight average molecular weights from 4000 to 4,000,000; (6) polyurethanes; (7) polycarbonates; (8) synthetic rubbers—e.g., homopolymers and copolymers of butadienes; and (9) homopolymers and copolymers formed from monomers containing ethylenic unsaturation such as polymerized forms of any of the various ethylenically unsaturated monomers, such as polyalkylenes—e.g. polyethylene and polypropylene; poly(vinyl alcohol); polystyrene; poly(acrylic and methacrylic acids and esters)-e.g. poly(methyl methacrylate) and poly(ethyl acrylate), as well as copolymer variants. The polymerizable compound and the polymeric binder can be employed together in widely varying proportions, including polymerizable compound ranging from 3-97 percent by weight of the film forming component and polymeric binder ranging from 97-3 percent by weight of the film forming component. A separate polymeric binder, although preferred, is not an essential part of the light curable film and is most commonly omitted when the polymerizable compound is itself a polymer.

Various photoinitiators can be selected for use in the above-described imaging systems. Preferred photoinitators consist of an organic dye.

The amount of organic dye to be used is preferably in the range of from 0.1 to 5% by weight based on the total weight of the photopolymerization composition, preferably from 0.2 to 3% by weight.

The organic dyes for use as photoinitiators in the present invention may be suitably selected from conventionally known compounds having a maximum absorption wavelength falling within a range of 300 to 1000 nm. High sensitivity can be achieved by selecting a desired dye having an absorption spectrum that overlaps with the absorption spectrum of the corresponding color absorbing material of the multicolor mask described above and, optionally, adjusting the absorption spectrum to match the light source to be used. Also, it is possible to suitably select a light source such as blue, green, or red, or infrared LED (light emitting diode), solid state laser, OLED (organic light emitting diode) or laser, or the like for use in image-wise exposure to light.

Specific examples of the photoinitiator organic dyes include 3-ketocoumarin compounds, thiopyrylium salts, naphthothiazolemerocyanine compounds, merocyanine compounds, and merocyanine dyes containing thiobarbituric acid, hemioxanole dyes, and cyanine, hemicyanine, and merocyanine dyes having indolenine nuclei. Other examples of the organic dyes include the dyes described in Chemistry of Functional Dyes (1981, CMC Publishing Co., Ltd., pp. 393-416) and Coloring Materials (60 [4], 212-224, 1987). Specific examples of these organic dyes include cationic methine dyes, cationic carbonium dyes, cationic quinoimine dyes, cationic indoline dyes, and cationic styryl dyes. Examples of the above-mentioned dyes include keto dyes such as coumarin dyes (including ketocoumarin and sulfonocoumarin), merostyryl dyes, oxonol dyes, and hemioxonol dyes; nonketo dyes such as nonketopolymethine dyes, triarylmethane dyes, xanthene dyes, anthracene dyes, rhodamine dyes, acridine dyes, aniline dyes, and azo dyes; nonketopolymethine dyes such as azomethine dyes, cyanine dyes, carbocyanine dyes, dicarbocyanine dyes, tricarbocyanine dyes, hemicyanine dyes, and styryl dyes; quinoneimine dyes such as azine dyes, oxazine dyes, thiazine dyes, quinoline dyes, and thiazole dyes.

Preferably, the photoinitiator organic dye is a cationic dye-borate anion complex formed from a cationic dye and an anionic organic borate. The cationic dye absorbs light having a maximum absorption wavelength falling within a range from 300 to 1000 nm and the anionic borate has four R groups, of which three R groups each represents an aryl group which may have a substitute, and one R group is an alkyl group, or a substituted alkyl group. Such cationic dye-borate anion complexes have been disclosed in U.S. Pat. Nos. 5,112,752, 5,100,755, 5, 075,393, 4,865,942, 4,842,980, 4,800,149, 4,772,530, and 4,772,541, which are incorporated herein by reference.

When the cationic dye-borate anion complex is used as the organic dye in the photopolymerization compositions of the invention, it does not require to use the organoborate salt. However, to increase the photopolymerization sensitivity, it is prefered to use an organoborate salt in combination with the cationic dye-borate complex. The organic dye can be used singly or in combination.

Specific examples of the above-mentioned cationic dye-borate salts are given below. However, it should be noted that the present invention is not limited to these examples.

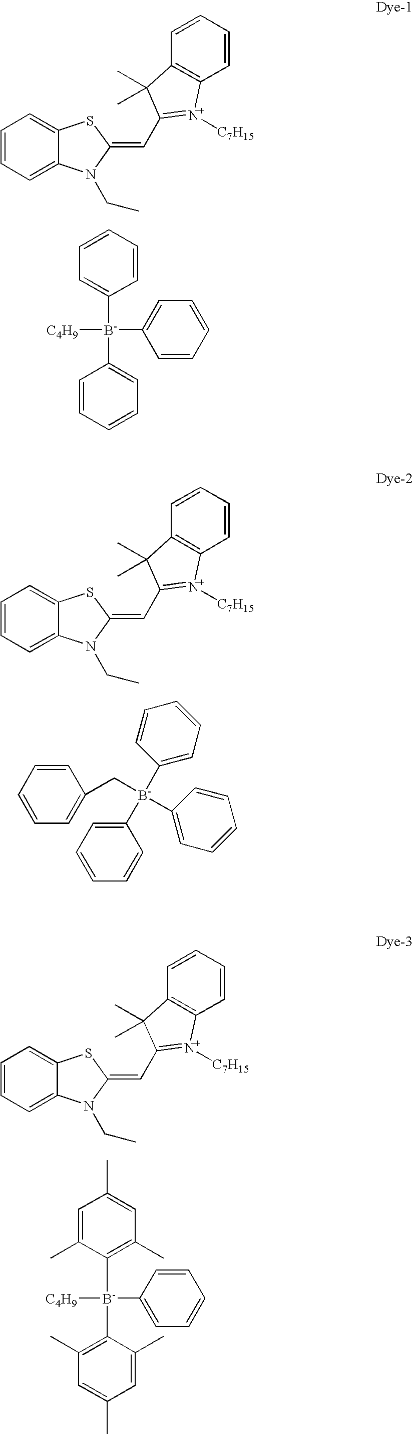

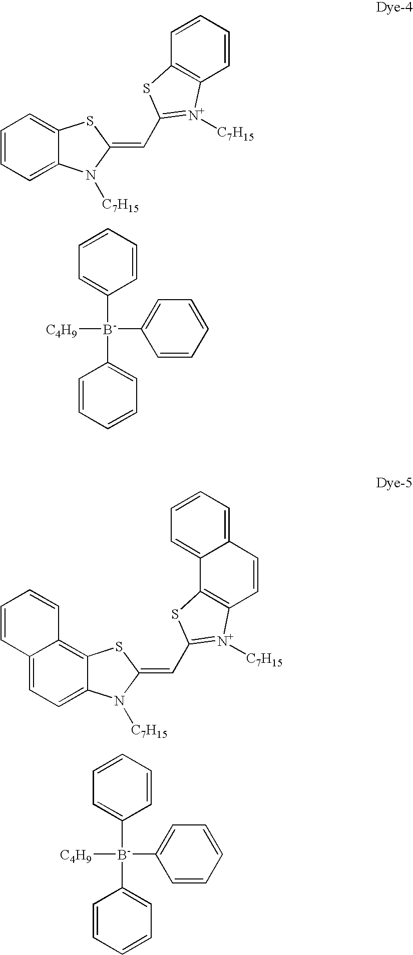

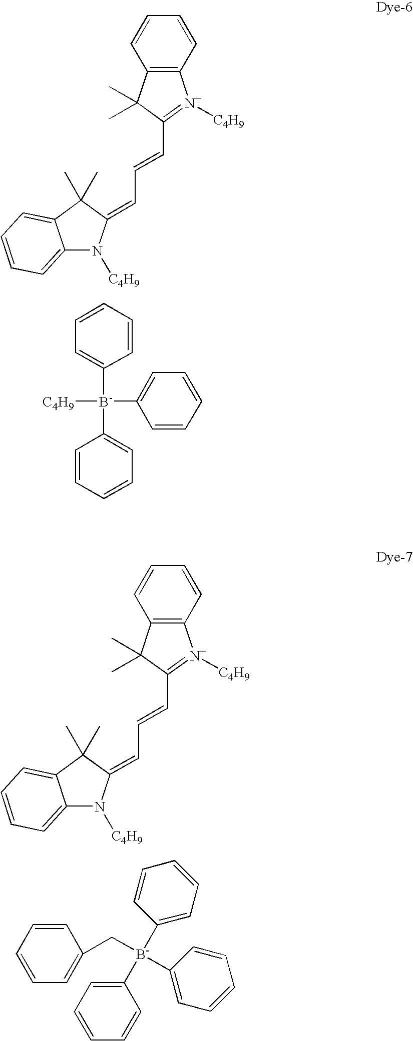

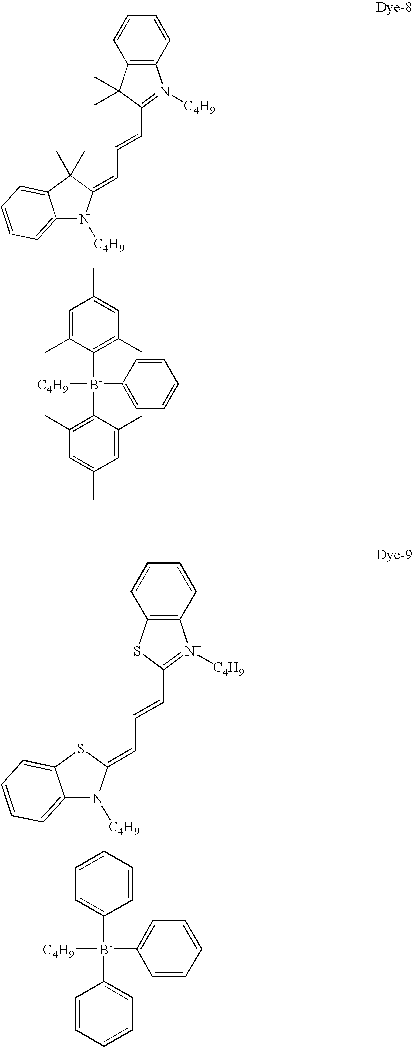

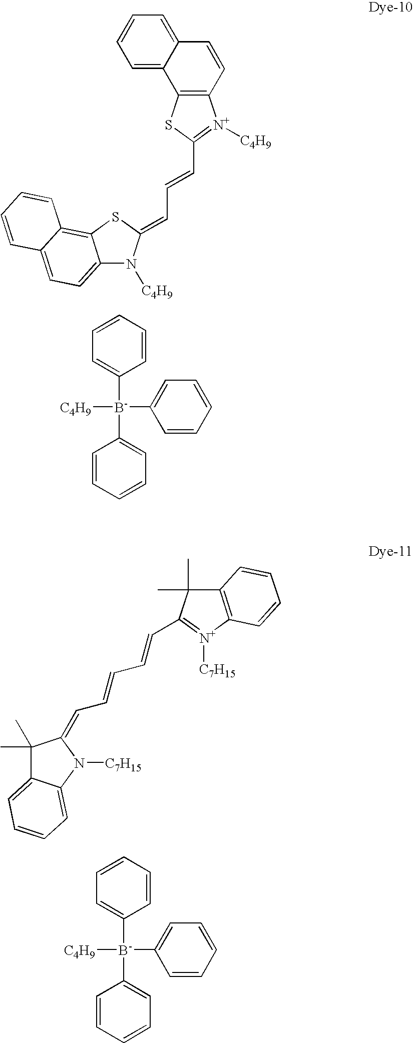

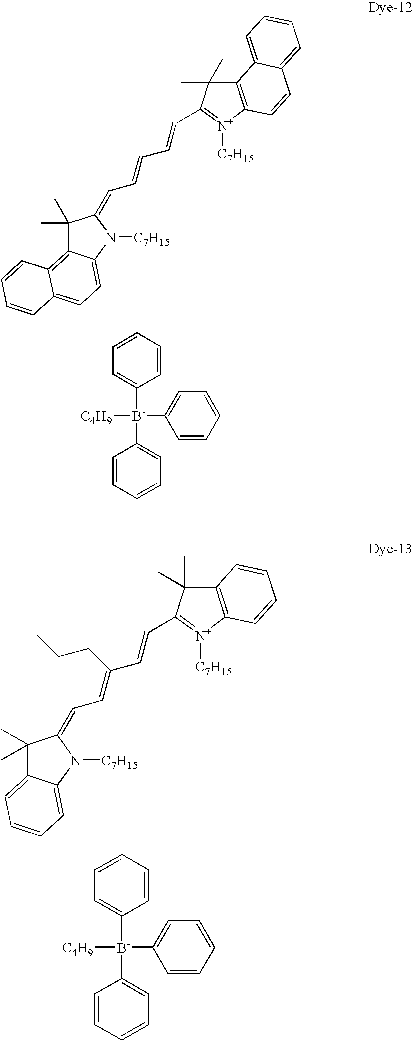

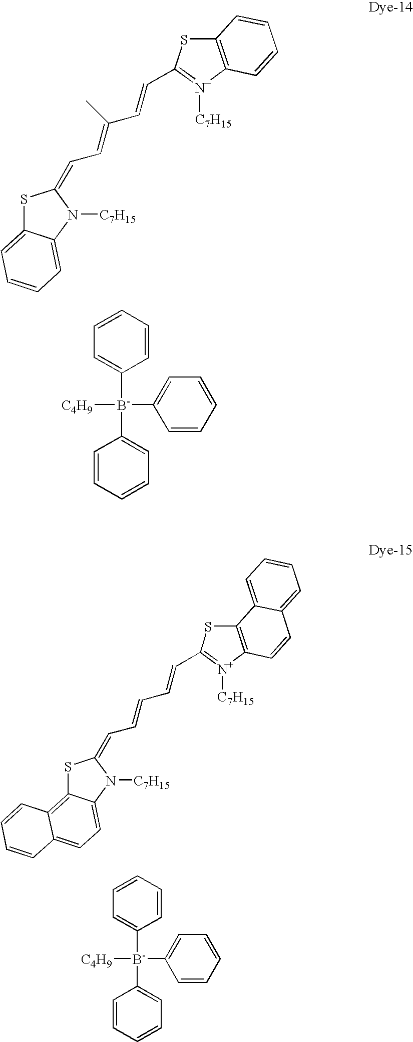

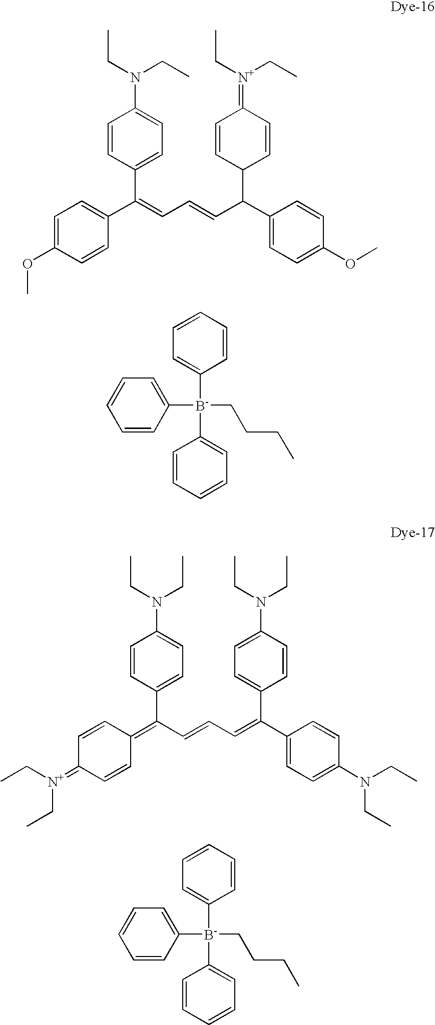

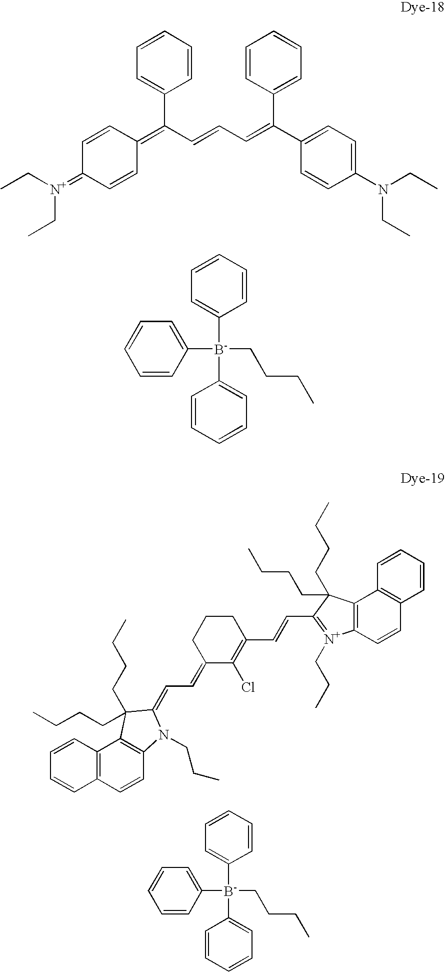

It may be preferable to use the photoinitiator in combination with an organic borate salt such as disclosed in U.S. Pat. Nos. 5,112,752; 5,100,755; 5,057,393; 4,865,942; 4,842,980; 4,800,149; 4,772,530 and 4,772,541. If used, the amount of borate compound contained in the photopolymerization composition of the invention is preferably from 0% to 20% by weight based on the total amount of photopolymerization composition. The borate salt useful for the photosensitive composition of the present invention is represented by the following general formula (I).

[BR₄]⁻Z⁺

where Z represents a group capable of forming cation and is not light sensitive, and [BR4]⁻ is a borate compound having four R groups which are selected from an alkyl group, a substituted alkyl group, an aryl group, a substituted aryl group, an aralkyl group, a substituted aralkyl group, an alkaryl group, a substituted alkaryl group, an alkenyl group, a substituted alkenyl group, an alkynyl group, a substituted alkynyl group, an alicyclic group, a substituted alicyclic group, a heterocyclic group, a substituted heterocyclic group, and a derivative thereof. Plural Rs may be the same as or different from each other. In addition, two or more of these groups may join together directly or via a substituent and form a boron-containing heterocycle. Z+ does not absorb light and represents an alkali metal, quaternary ammonium, pyridinium, quinolinium, diazonium, morpholinium, tetrazolium, acridinium, phosphonium, sulfonium, oxosulfonium, iodonium, S, P, Cu, Ag, Hg, Pd, Fe, Co, Sn, Mo, Cr, Ni, As, or Se.

Specific examples of the above-mentioned borate salts are given below. However, it should be noted that the present invention is not limited to these examples.

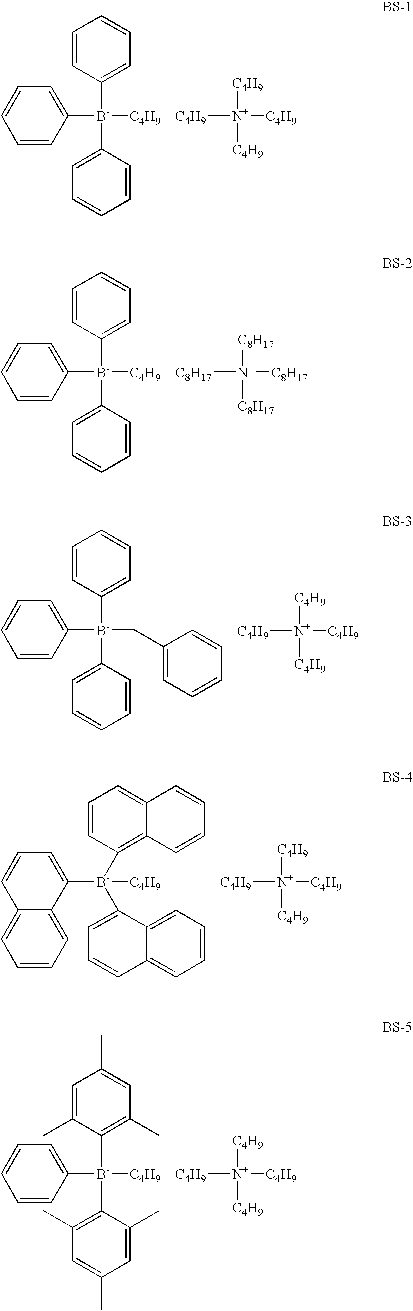

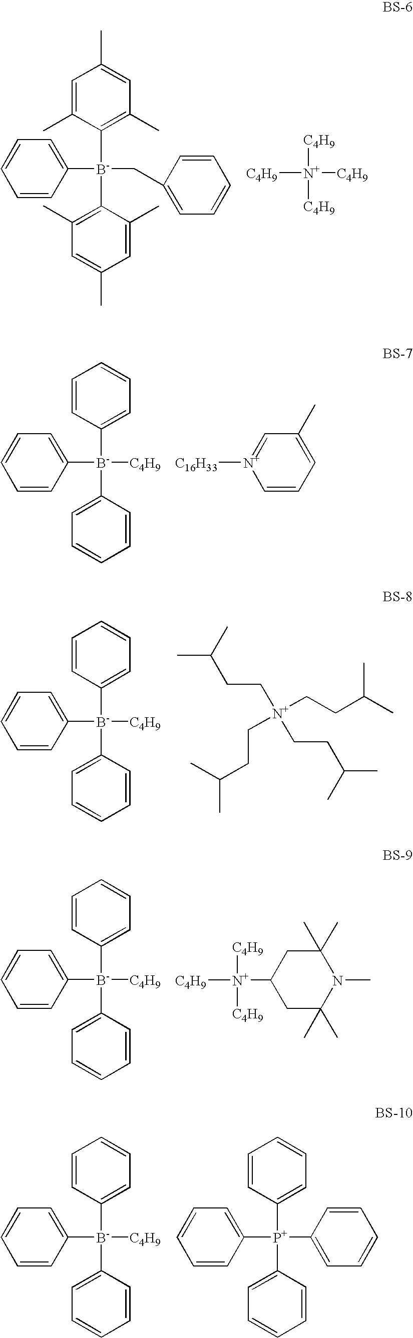

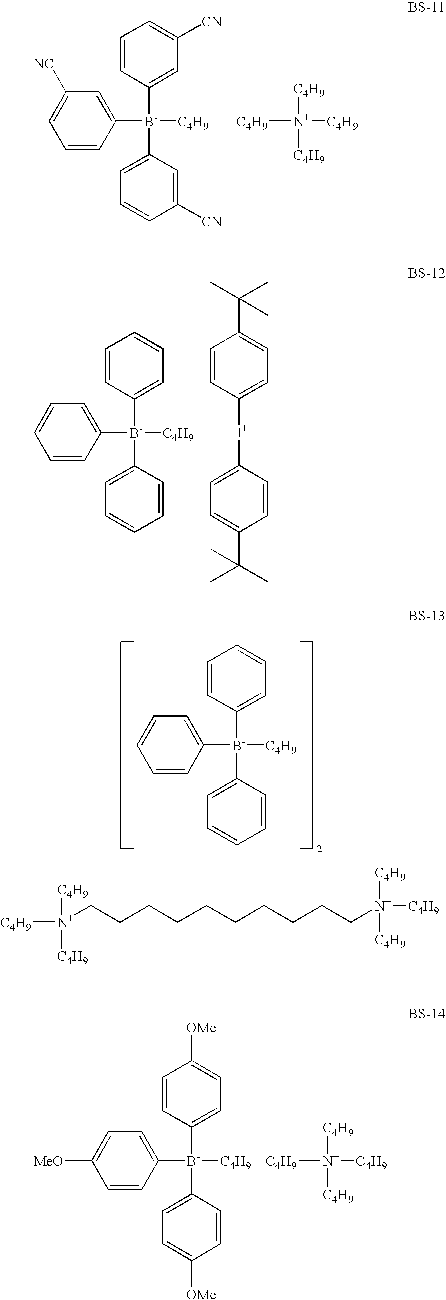

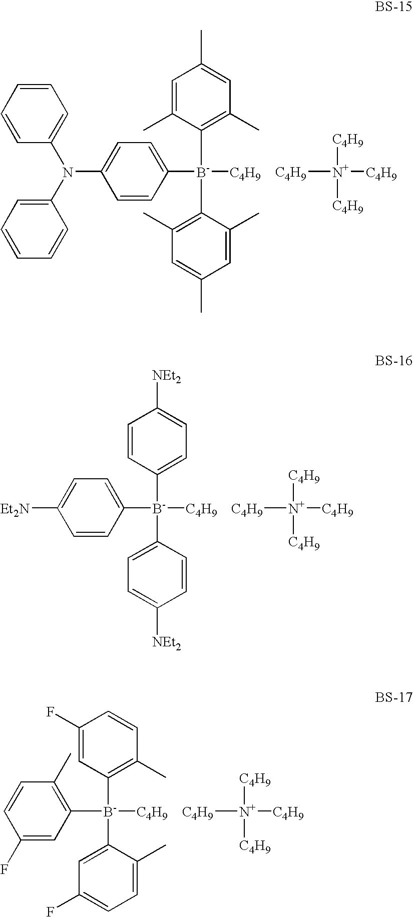

Various additives can be used together with the photoinitiator system to affect the polymerization rate. For example, a reducing agent such as an oxygen scavenger or a chain-transfer aid of an active hydrogen donor, or other compound can be used to accelerate the polymerization. An oxygen scavenger is also known as an autoxidizer and is capable of consuming oxygen in a free radical chain process. Examples of useful autoxidizers are N,N-dialkylanilines. Examples of preferred N,N-dialkylanilines are dialkylanilines substituted in one or more of the ortho-, meta-, or para-position by the following groups: methyl, ethyl, isopropyl, t-butyl, 3,4-tetramethylene, phenyl, trifluoromethyl, acetyl, ethoxycarbonyl, carboxy, carboxylate, trimethylsilymethyl, trimethylsilyl, triethylsilyl, trimethylgermanyl, triethylgermanyl, trimethylstannyl, triethylstannyl, n-butoxy, n-pentyloxy, phenoxy, hydroxy, acetyl-oxy, methylthio, ethylthio, isopropylthio, thio-(mercapto-), acetylthio, fluoro, chloro, bromo and iodo. Representative examples of N,N-dialkylanilines useful in the present invention are 4-cyano-N,N-dimethylaniline, 4-acetyl-N,N-dimethylaniline, 4-bromo-N,N-dimethylaniline, ethyl 4-(N,N-dimethylamino)benzoate, 3-chloro-N,N-dimethylaniline, 4-chloro-N,N-dimethylaniline, 3-ethoxy-N,N-dimethylaniline, 4-fluoro-N,N-dimethylaniline, 4-methyl-N,N-dimethylaniline, 4-ethoxy-N,N-dimethylaniline, N,N-dimethylaniline, N,N-dimethylthioanicidine 4-amino-N,N-dimethylaniline, 3-hydroxy-N,N-dimethylaniline, N,N,N′,N′-tetramethyl-1,4-dianiline, 4-acetamido-N,N-dimethylaniline, 2,6-diisopropyl-N,N-dimethylaniline (DIDMA), 2,6-diethyl-N,N-dimethylaniline, N,N, 2,4,6-pentamethylaniline (PMA) and p-t-butyl-N,N-dimethylaniline.

It may be preferable to use the photoinitiator in combination with a disulfide coinitiator. Examples of useful disulfides are described in U.S. Pat. No. 5,230,982 which is incorporated herein by reference. Two of the most preferred disulfides are mercaptobenzothiazo-2-yl disulfide and 6-ethoxymercaptobenzothiazol-2-yl disulfide. In addition, thiols, thioketones, trihalomethyl compounds, lophine dimer compounds, iodonium salts, sulfonium salts, azinium salts, organic peroxides, and azides, are examples of compunds useful as polymerization accelerators.

Other additives which can be incorporated into the light curable coatings include polymeric binders, fillers, pigments, surfactants, adhesion modifiers, and the like. To facilitate coating on the support and functional layers the light curable film composition is usually dispersed in a solvent to create a solution or slurry, and then the liquid is evaporatively removed, usually with heating, after coating. Any solvent can be employed for this purpose which is inert toward the film forming components and addenda of the light curable film.

Once a light curable layer is exposed, it can be developed by any means known the art. Development is the process by which the soluble portions of the light curable layer are removed. Methods for developing typically include exposure to a selective solvent, heating, or combinations thereof. A liquid developer can be any convenient liquid which is capable of selectively removing the light curable layer in uncured areas. The exposed light curable layer can be sprayed, flushed, swabbed, soaked, sonicated, or otherwise treated to achieve selective removal. In its simplest form the liquid developer can be the same liquid employed as a solvent in coating the light curable film. In some instances the photoresist is not rendered soluble where it is ultimately to be removed, but is instead rendered susceptible to a particular reaction that occurs during exposure to a development solution which then permits solubility.

In patterning processes where the light cured film is not intended to be part of the final article, it needs to be removed after it has been used to successfully pattern an area. This removal can be accomplished with any means known in the art, included plasma treatments, especially plasmas including oxygen, solvent based stripping, and mechanical or adhesive means. In many embodiments the curable layer is simply a layer used to pattern another functional layer. However, circumstances may exist in which the light cured layer is also the functional layer. Examples of this are the use of a curable layer as a dielectric due to its insulating behavior, or as a structural element such as a small wall or microcell due to its mechanical properties. This use of curable layers as functional layers is not limited to the above examples.

### [Methods of Combining Light and Mask Color]

In the process for the article of this invention there is required a light source that emits light of some spectrum, the back side multicolor mask that contains at least two color records in which each is capable of absorbing light of some spectrum, and a curable layer that is capable of responding to light of some spectrum.

The system can function in several modes:
(1) White light, defined as light of a very broad visible spectrum, can be used as the illumination source. In this case, it is required that the light curable layer have a sensitivity distribution that substantially matches the absorption spectrum of the target color record of the back side color mask. Substantially matching spectrum is defined as the integrated product of the two spectra, each normalized to an area of 1, exceeding 0.5, preferably exceeding 0.75, most preferably exceeding 0.9.
(2) Colored light, as defined by light of a narrow spectrum, can be used as the illumination source. In this case, the absorption spectrum of light curable layer can be made to substantially match the spectrum of the emitted light, or the spectrum can be broad. The former case may be desirable for improved sensitivity of the light curable layer and reduced cross talk between layers, while the latter case may be desirable for allowing several process steps to employ a single light curable layer formulation.

In some cases it may be desirable to apply a black layer to part of the mask. Such a black layer has the property of absorbing substantially all of the light in those areas of the mask having the black layer. If, for example, large areas of the final product are desired to have no patterning, a black printed mask can be used in those areas.

In much of the preceding discussion the color mask is referred to as having color absorption corresponding to the traditional observable colors of the visible spectrum. However, this applies a limitation to the number of individual mask levels that can be accomplished with this approach. In principle a high number of individual color records can be used provided that each color record can be independently addressed in the process. In addition, by utilizing infrared and ultraviolet portions of the spectrum, the number of mask levels may further be increased. It is envisioned that upwards of 6 individual mask levels can be achieved with the current invention.

In this process, light passes through the colored mask and then through the previously applied functional layers on the front of the substrate. As a result, the light must pass through the previously applied layers with weak enough modulation as to not overly affect the resulting images formed on the applied light curable layers. The requirement for transparency of the applied functional layers is thus limited to having an acceptably low effect on the curable layer imaging process. In principle therefore, the previously applied can absorb light uniformly as long as this absorption is low, preferably having an optical density of less than 0.5. Furthermore, the materials can absorb very strongly but only in regions where the imaging chemistry is not being used, or where these spectral ranges have been used but in prior stages of the manufacture of the article. Furthermore, the final layer in the process can be of any opacity, since additional patterning is not required on top.

### [Patterning Etching Methods]

An aspect of this invention is the ability to at will use one of the colors of the backside mask to form a pattern on the front side of the item by the direction light through the backside to cause an effect on the frontside. A number of methods can be used to cause the frontside patterning.
(a) A functional material can be coated uniformly upon the front side of the item and then overcoated with a resist material that hardens when it is exposed to light from the back side. The hardened material is then more difficult to remove, so in a subsequent development step, the resist is patterned to have openings where no light has struck. The item can then be exposed to a material that attacks the functional layer, thus removing it where no light has struck. This is a negative etch process. FIGS. 18-20A illustrate how in the present invention a multicolor mask is used in a negative etch patterning sequence.
(b) A functional material can be coated uniformly upon the front side of the item and then overcoated with a resist material that softens when it is exposed to light from the back side. The softened materials is then easier to remove, so in a subsequent development step, the resist is patterned to have openings where light has struck. The item can then be exposed to a material that attacks the functional layer, thus removing it where light has struck. This is a positive etch process.
(c) A resist material can be coated followed by exposure and development step as outlined in (a) or (b). This will yield a resist pattern that has holes in it. This can then be overcoated with a uniform layer of a functional material. If the entire item is then treated with a material that attacks the remaining photoresist under the functional material, it can remove material where photoresist resides. This will leave functional material where there was originally no photoresist. This is a liftoff process. FIGS. 15-17A illustrate how in the present invention a multicolor mask is used in a liftoff patterning process
(d) A number of deposition processes employing both liquids and vapor phase chemical delivery can be tailored to operate in a manner where material selectively deposits only in certain areas. For example, a resist material can be coated followed by exposure and development step as outlined in (a) or (b). This is followed by a deposition process that leads to material being deposited only in those regions where no resist material remains. The entire item is then treated with a material that attacks the remaining resist. This is selective deposition. FIGS. 21-23A illustrate how a multicolor mask can be used in the present invention using a selective deposition patterning process.

### [Supports]

A support can be used for supporting the device during manufacturing, testing, and/or use. The skilled artisan will appreciate that a support selected for commercial embodiments may be different from one selected for testing or screening various embodiments. In some embodiments, the support does not provide any necessary electrical function for the device. This type of support is termed a “non-participating support” in this document. Useful materials can include organic or inorganic materials. For example, the support may comprise inorganic glasses, ceramic foils, polymeric materials, filled polymeric materials, acrylics, epoxies, polyamides, polycarbonates, polyimides, polyketones, poly(oxy-1,4-phenyleneoxy-1,4-phenylenecarbonyl-1,4-phenylene) (sometimes referred to as poly(ether ether ketone) or PEEK), polynorbornenes, polyphenyleneoxides, poly(ethylene naphthalenedicarboxylate) (PEN), poly(ethylene terephthalate) (PET), poly(ether sulfone) (PES), poly(phenylene sulfide) (PPS), and fiber-reinforced plastics (FRP).

A flexible support is used in some embodiments. This allows for roll-to-roll or roll-to-sheet processing, which may be continuous, providing economy of scale and economy of manufacturing over flat and/or rigid supports. The flexible support chosen preferably is capable of wrapping around the circumference of a cylinder of less than about 50 cm diameter, more preferably 25 cm diameter, most preferably 10 cm diameter, without distorting or breaking, using low force as by unaided hands. The preferred flexible support may be rolled upon itself.

If flexibility is not a concern, then the substrate may be a wafer or sheet made of materials including glass as well as any other transparent material.

The thickness of the substrate may vary, and according to particular examples it can range from about 10 μm to about 1 mm. Preferably, the thickness of the substrate is in the range from about 10 μm to about 300 μm. Provided the exposing light source is sufficiently collimated to limit the angular spread of light through the support layer, even thicker substrates can be tolerated. It may be particularly advantageous for optical considerations to coat or cast the main support layer directly onto the color absorbing layers of the multicolor mask. In some embodiments, the support is optional, particularly when support layer is a functional layer or a color absorbing layer of the multicolor mask. In these embodiments the mask image is as close as possible to the top side of the substrate on which will be the active devices.

In addition, the multicolor mask and support may be combined with a temporary support. In such an embodiment, a support may be detachably adhered or mechanically affixed to the multicolor mask.

### [Electronic Materials]

Any material that can form a film on the substrate can be patterned with this invention, as long as the appropriate etching and or deposition conditions are chosen. General classes of functional materials that can be used include conductors, dielectrics or insulators, and semiconductors.

Conductors can be any useful conductive material. A variety of conductor materials known in the art, are also suitable, including metals, degenerately doped semiconductors, conducting polymers, and printable materials such as carbon ink, silver-epoxy, or sinterable metal nanoparticle suspensions. For example, the conductor may comprise doped silicon, or a metal, such as aluminum, chromium, gold, silver, nickel, copper, tungsten, palladium, platinum, tantalum, and titanium. Conductors can also include transparent conductors such as indium-tin oxide (ITO), ZnO, SnO₂, or In₂O₃. Conductive polymers also can be used, for example polyaniline, poly(3,4-ethylenedioxythiophene)/poly(styrene sulfonate) (PEDOT:PSS). In addition, alloys, combinations, and multilayers of these materials may be most useful.

The thickness of the conductor may vary, and according to particular examples it can range from about 5 to about 1000 nm. The conductor may be introduced into the structure by chemical vapor deposition, sputtering, evaporation and/or doping, or solution processing.

A dielectric electrically insulates various portions of a patterned circuit. A dielectric layer may also be referred to as an insulator or insulating layer. The dielectric should have a suitable dielectric constant that can vary widely depending on the particular device and circumstance of use. For example, a dielectric constant from about 2 to 100 or even higher is known for a gate dielectric. Useful materials for a dielectric may comprise, for example, an inorganic electrically insulating material. Specific examples of materials useful for the gate dielectric include strontiates, tantalates, titanates, zirconates, aluminum oxides, silicon oxides, tantalum oxides, titanium oxides, silicon nitrides, barium titanate, barium strontium titanate, barium zirconate titanate, zinc selenide, and zinc sulfide. In addition, alloys, combinations, and multilayers of these examples can be used as a dielectric. Of these materials, aluminum oxides, silicon oxides, and silicon nitride are useful. The dielectric may comprise a polymeric material, such as polyvinylidenedifluoride (PVDF), cyanocelluloses, polyimides, polyvinyl alcohol, poly(4-vinylphenol), polystyrene and substituted derivatives thereof, poly(vinyl naphthalene) and substituted derivatives, and poly(methyl methacrylate) and other insulators having a suitable dielectric constant. The gate electric may comprise a plurality of layers of different materials having different dielectric constants.

The thickness of a dielectric layer may vary, and according to particular examples it can range from about 15 to about 1000 nm. The dielectric layer may be introduced into the structure by techniques such as chemical vapor deposition, sputtering, atomic layer deposition, evaporation, or a solution process.

Semiconductors used in this system may be organic or inorganic. Inorganic semiconductors include classes of materials exhibiting covalently bonded lattices, and may also include amorphous materials where the lattice exhibits only short range order. Examples of useful semiconducting materials are single elements such as silicon or germanium, and compound semiconductors such as gallium arsenide, gallium nitride, cadmium sulfide, and zinc oxide. Useful organic semiconductors include linear acenes such as pentacenes, naphthalenediimides such as those described in co-pending patent applications, perylenediimides, polythiophenes, polyfluorenes.

In typical applications of a thin film transistor, the desire is for a switch that can control the flow of current through the device. As such, it is desired that when the switch is turned on a high current can flow through the device. The extent of current flow is related to the semiconductor charge carrier mobility. When the device is turned off, it is desired that the current flow be very small. This is related to the charge carrier concentration. Furthermore, it is desired that the device be weakly or not at all influenced by visible light. In order for this to be true, the semiconductor band gap must be sufficiently large (>3 eV) so that exposure to visible light does not cause an inter-band transition. A material that is capable of yielding a high mobility, low carrier concentration, and high band gap is ZnO.

The entire process of making the thin film transistor or electronic device of the present invention, or at least the production of the thin film semiconductor, is preferably carried out below a maximum support temperature of about 200° C., more preferably below 150° C., most preferably below about 140° C., and even more preferably below about 100° C., or even at temperatures around room temperature (about 25° C. to 70° C.). The temperature selection generally depends on the support and processing parameters known in the art, once one is armed with the knowledge of the present invention contained herein. These temperatures are well below traditional integrated circuit and semiconductor processing temperatures, which enables the use of any of a variety of relatively inexpensive supports, such as flexible polymeric supports and the multicolor mask. Thus, the invention enables production of relatively inexpensive circuits containing thin film transistors.

Electronically or optically active layers layers may be formed and doped using solution processes, vacuum vapor deposition techniques, or atmospheric vapor deposition processes such as those described in co-pending patent applications U.S. Ser. No. 11/392,006 and U.S. Ser. No. 11/392,007, both filed Mar. 29, 2006.

### [Applications]

The patterning methods of this invention are preferably used to create electrically and optically active components that are integrated on a substrate of choice. Circuit components can comprise transistors, resistors, capacitors, conductors, inductors, diodes, and any other electronics components that can be constructed by selecting the appropriate patterning and materials. Optically functional components can comprise waveguides, lenses, splitters, diffusers, brightness enhancing films, and other optical circuitry. Structural components can comprise wells, selective patterns of fillers and sealants, patterned barrier layers, walls and spacers.

Electronic devices in which TFTs and other devices are useful include, for example, more complex circuits, e.g., shift registers, integrated circuits, logic circuits, smart cards, memory devices, radio-frequency identification tags, backplanes for active matrix displays, active-matrix displays (e.g. liquid crystal or OLED), solar cells, ring oscillators, and complementary circuits, such as inverter circuits, for example, in which a combination of n-type and p-type transistors are used. In an active matrix displays, a transistor made according to the present invention can be used as part of voltage hold circuitry of a pixel of the display. In such devices, the TFTs are operatively connected by means known in the art.

One example of a microelectronic device is an active-matrix liquid-crystal display (AMLCD). One such device is an optoelectronic display that includes elements having electrodes and an electro-optical material disposed between the electrodes. A connection electrode of the transparent transistor may be connected to an electrode of the display element, while the switching element and the display element overlap one another at least partly. An optoelectronic display element is here understood to be a display element whose optical properties change under the influence of an electrical quantity such as current or voltage such as, for example, an element usually referred to as liquid crystal display (LCD). The presently detailed transistor has sufficient current carrying capacity for switching the display element at such a high frequency that the use of the transistor as a switching element in a liquid crystal display is possible. The display element acts in electrical terms as a capacitor that is charged or discharged by the accompanying transistor. The optoelectronic display device may include many display elements each with its own transistor, for example, arranged in a matrix. Certain active matrix pixel designs, especially those supplying a display effect that is current driven, may require several transistors and other electrical components in the pixel circuit.

### EXAMPLES

The following non-limiting examples further describe the practice of the instant invention.

### Example 1

### Multicolor Mask Formed by Direct Printing Process

In this example, a multicolor mask was prepared containing 3 color absorbing layers, with each color corresponding to an individual functional layer of an array of thin film transistor devices. The design for the gate layer of the array of thin film transistor devices was converted into a black and white bitmap file. The design for the semiconductor layer of the array of thin film transistor devices was converted into another black and white bitmap file. The design for the source and drain layer of the array of thin film transistor device was converted into a third black and white bitmap file. These bitmaps were then imported into the blue channel, green channel, and red channel of a single color image file using Photoshop 6.0. In this full color image, the blue channel contained the gate layer design as a yellow pattern. The green channel contained the semiconductor layer design as a magenta pattern. The red channel contained the source and drain design as a cyan pattern. This color image was printed onto a transparent support using a Kodak Professional 8670 Thermal Printer loaded with Kodak Professional Ektatherm XLS transparency media. The resulting multicolor mask was laminated to the nonconductive side of a flexible ITO film purchased from Bekaert Specialty films.

### Example 2

### Multicolor Mask Formed by Photolithography Process

In this example, a multicolor mask was prepared containing 3 color absorbing layers, with each color corresponding to an individual functional layer of an array of thin film transistor devices. Chrome on glass masks for the gate layer (CG-1), semiconductor and dielectric layers (CG-2), and source and drain layers (CG-3) of the array of thin film transistor devices were obtained from Applied Image Incorporated. A 0.7 mm thick borosilicate glass support was washed for 10 minutes by treating with a solution of 70% sulfuric acid and 30% of a 30% solution of hydrogen peroxide maintained at approximately 100 C. After washing, the clean glass was spin coated (at 1000 RPM) with Color Mosaic SC3200L (purchased from Fujifilm Electronic Materials Co., Ltd.). SC-3200L is a UV curable photoresist containing 3-5% of a cyan pigment, 7-9% of a methacrylate derivative copolymer, 7-9% of a polyfunctional acrylate resin and a UV photosensitizer dispersed in a mixture of propylene glycol monomethyl ether acetate and ethyl-3-ethoxy-propionate. The coated glass slide was baked for 1 minute at 95 C, and exposed for 1 minute to a pattern of UV light using a 200W Mercury-Xenon lamp, with mask CG-3 (contact exposure). The cyan photoresist layer was developed for one minute with a a solution of 0.03 M tetramethylammonium hydroxide/0.03 M diethanolamine in water, rinsed with water, and baked for 5 minutes at 200 C. The sample was then spin coated (at 1000 RPM) with Color Mosaic SM3000L (purchased from Fujifilm Electronic Materials Co., Ltd.). SM-3000L is a UV curable photoresist containing 4-6% of a magenta pigment, 6-8% of a methacrylate derivative copolymer, 6-8% of a polyfunctional acrylate resin and a UV photosensitizer dispersed in a mixture of propylene glycol monomethyl ether acetate and ethyl-3-ethoxy-propionate. The coated glass slide was baked for 1 minute at 95 C, and exposed for 1 minute to a pattern of UV light using a 200W Mercury-Xenon lamp, with mask CG-2 (contact exposure). The magenta photoresist layer was developed for one minute with a solution of 0.03 M tetramethylammonium hydroxide/0.03 M diethanolamine in water, rinsed with water, and baked for 5 minutes at 200 C. The resulting glass substrate contained an array of registered cyan and magenta patterns. The sample was then spin coated (at 1000 RPM) with Color Mosaic SY3000L, (purchased from Fujifilm Electronic Materials Co., Ltd.). SY-3000L is a UV curable photoresist containing 3-5% of a yellow pigment, 7-9% of a methacrylate derivative copolymer, 7-9% of a polyfunctional acrylate resin and a UV photosensitizer dispersed in a mixture of propylene glycol monomethyl ether acetate and ethyl-3-ethoxy-propionate. The coated glass slide was baked for 1 minute at 95 C, and exposed for 1 minute to a pattern of UV light using a 200W Mercury-Xenon lamp, with mask CG-1 (contact exposure). The yellow photoresist layer was developed for one minute with a a solution of 0.03 M tetramethylammonium hydroxide/0.03 M diethanolamine in water, rinsed with water, rinsed with water, and baked for 5 minutes at 200 C. The resulting multicolor mask contained an array of registered cyan, magenta, and yellow patterns.

### Example 3

### Blue-Curable Film Formulation

A coating solution C-1 for the blue light curable film was prepared as follows. A solution of blue sensitive photoinitiator was prepared by adding 0.03 g of photoinitiator A to 3 grams of toluene.

### Photoinitiator A:

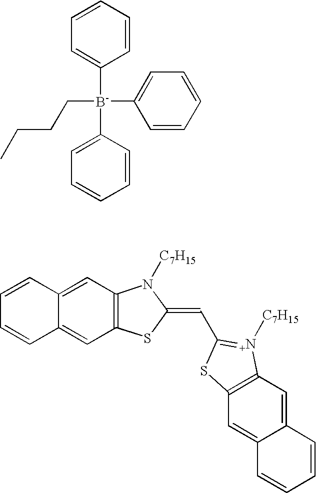

In a separate vial, five grams of polymethylmethacrylate (PMMA) (MW ˜75K) were dissolved in 45 g of anisole. To 2.9 g of the resulting PMMA solution, 0.95 g of trimethylolpropane triacrylate and 0.5 g of the solution of photoinitiator A were added.

### Green-Curable Film Formulation

A coating solution C-2 for the green light curable film was prepared as follows. A solution of green sensitive photoinitator was prepared by adding 0.03 g of photoinitiator B to 3 grams of anisole. In a separate vial, five grams of PMMA (MW ˜75K) were dissolved in 45 g of anisole. To 2.9 g of the resulting PMMA solution, 0.95 g of trimethylolpropane triacrylate and 0.5 g of the solution of photoinitiator B were added.

### Photoinitiator B:

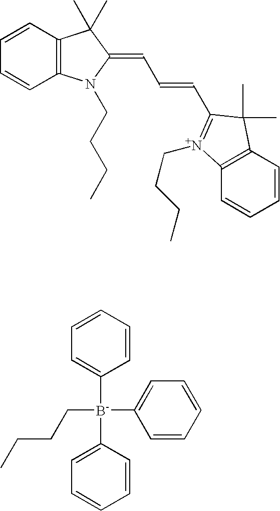

### Example 4

### Red-Curable Film Formulation

A coating solution C-3 for the red light curable film was prepared as follows. A solution of red sensitive photoinitator was prepared by adding 0.025 g of photoinitiator C to 2.5 grams of anisole. In a separate vial, five grams of PMMA (MW ˜75K) were dissolved in 45 g of anisole. To 2.9 g of the resulting PMMA solution, 0.95 g of trimethylolpropane triacrylate and 0.5 g of the solution of photoinitiator C were added.

### Photoinitiator C:

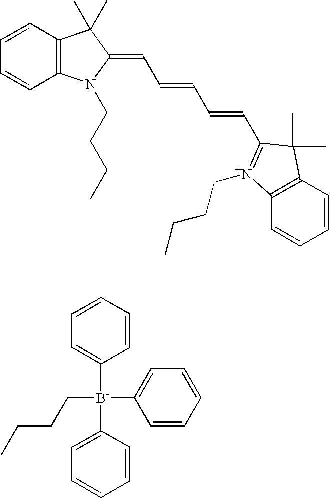

### Example 5

### Registered Conductive Layer Patterns on Flexible Film with Single Multicolor Mask

The multicolor mask resulting from example A was laminated to the nonconductive side of a flexible ITO film purchased from Bekaert Specialty films. The conductive side was coated with blue-curable coating solution C-1 by spin coating at a rate of 1000 RPM. The sample was baked for 1 minute at 80 C, and loaded in a glass cell purged with nitrogen. The sample was illuminated for ⅛″ using a 300 W GE Mini Multi-Mirror FHS projection lamp in such fashion that illuminating light passes through the multicolor mask before reaching the blue-curable coating. Uncured portions of the blue-curable coating were removed by developing for 30 seconds in methylisobutylketone (MIBK). These steps resulted in formation of a patterned polymer film in registry with the yellow pattern on the color-encoded mask. The ITO layer was etched in HCl:H₂O (1:1) to remove portions of the ITO not covered by the blue-light cured film. Portions of the ITO protected by the pattern of blue-light cured film remained, resulting in a patterned ITO layer and a patterned polymer film in registry with the yellow pattern on the multicolor mask. The sample was then spin coated with solution of silver nanoparticles and annealed at 110 C. The resulting semitransparent conductive film had a neutral density of 0.6. The silver nanoparticulate layer was coated with red-curable coating solution C-3 by spin coating at a rate of 1000 RPM. The sample was baked for 1 minute at 80 C, and exposed for 2″ using the exposure method previously described. The sample was illuminated for 2″ in such fashion that illuminating light passed through the multicolor mask, flexible film, patterned ITO layer, and silver nanoparticle layer before reaching the red-curable coating. Unexposed portions of the red-curable coating were removed by developing for 30 seconds in MIBK. These steps resulted in formation of a patterned polymer film in registry with the cyan pattern on the color-encoded mask. The silver layer was etched for 30 seconds using Kodak Ektacolor RA-4 bleach-fix solution to produce a patterned silver conductive film and a patterned red-cured polymer film in registry with the cyan pattern of the multicolor mask, a patterned blue-cured polymer film and a patterned ITO conductive film in registry with the yellow pattern of the multicolor mask.

### Example 6

### Thin Film Transistor

In this example, thin film transistors were prepared using a multicolor mask to pattern transparent electronic materials. Electrical characterization of the fabricated devices was performed with a Hewlett Packard HP 4156® parameter analyzer. Device testing was done in air in a dark enclosure.

The results were averaged from several devices. For each device, the drain current (Id) was measured as a function of source-drain voltage (Vd) for various values of gate voltage (Vg). Furthermore, for each device the drain current was measured as a function of gate voltage for various values of source-drain voltage. Vg was swept from minus 10 V to 40 V for each of the drain voltages measured, typically 5 V, 20 V, and 35 V, and 50 V. Mobility measurements were taken from the 35V sweep.

Parameters extracted from the data include field-effect mobility (μ), threshold voltage (Vth), subthreshold slope (S), and the ratio of Ion/Ioff for the measured drain current. The field-effect mobility was extracted in the saturation region, where Vd>Vg−Vth. In this region, the drain current is given by the equation (see Sze in Semiconductor Devices-Physics and Technology, John Wiley & Sons (1981)):

$${I}_{d} = \frac{W}{2 L} μ {{C}_{ox} ( {V}_{g} - {V}_{th} )}^{2}$$

Where, W and L are the channel width and length, respectively, and Cₒₓ is the capacitance of the oxide layer, which is a function of oxide thickness and dielectric constant of the material. Given this equation, the saturation field-effect mobility was extracted from a straight-line fit to the linear portion of the √I_{d} versus Vg curve. The threshold voltage, Vₜₕ, is the x-intercept of this straight-line fit.

The first step in fabricating the transistors was to prepare the multicolor mask in the identical fashion described in example 1. This mask was laminated to the nonconductive side of a piece of ITO glass. The conductive side was coated with blue-curable coating solution C-1 by spin coating at a rate of 1000 RPM. The sample was baked for 1 minute at 80 C, and loaded in a glass cell purged with nitrogen. The sample was illuminated for ⅛″ using a 300 W GE Mini Multi-Mirror FHS projection lamp in such fashion that illuminating light passes through the multicolor mask before reaching the blue-curable coating. Uncured portions of the blue-curable coating were removed by developing for 30 seconds in MIBK. These steps resulted in formation of a patterned polymer film in registry with the yellow pattern on the color-encoded mask, forming a series of stripes. The ITO layer was etched for 7 minutes in HCl:H2O (1:1) to remove portions of the ITO not covered by the blue-light cured film, forming a series of conducting gate lines. Portions of the ITO protected by the pattern of blue-light cured film remained, resulting in a patterned ITO layer and a patterned polymer film in registry with the yellow pattern on the multicolor mask. The mask layers were removed and an aluminum oxide film was deposited on the patterned ITO layer using a CVD process with trimethylaluminum and water as reactive materials entrained in a nitrogen carrier gas. Subsequently, a zinc oxide film was deposited using a CVD process and utilizing diethyl zinc and water as reactive materials entrained in a nitrogen carrier gas. To facilitate electrical contact to the ITO gate lines, the aluminum oxide and zinc oxide films did not cover the top 5 mm of the sample area. Metal source and drain contacts were deposited using vacuum evaporation through a shadow mask. Typical electrodes were of a size leading to a channel that was 480 microns wide by about 50 microns long, although due to small channel length variations mobilities were calculated using individually measured lengths. Devices were then tested for transistor activity. The transistors prepared using the multicolor mask yielded a mobility of 0.8 cm²/V-s.

The fabrication sequence employing a multicolor mask as outlined above allows for accurate placement of any number of transparent functional layers on the substrate even while exposing the substrate to varying temperature and solvent treatments. Further, even for large area substrates, there are no issues with dimensional distortion of the substrate or mechanical alignment errors leading to cumulative and catastrophic alignment errors. Use of the multicolor mask and visible light curable films provides a unique solution to the registration challenge without the need for expensive alignment equipment and processes.

### Parts List

10 Multicolor mask
11 Article
12 Support
14 Blue absorber
16 Red absorber
18 Green absorber
20 First transparent functional material
22 Blue-curable layer
24 Pattern of blue-curable material aligned to blue absorber in multicolor mask
26 Pattern of first transparent functional material aligned to blue absorber in multicolor mask
28 Second transparent functional material
30 Green-curable layer
32 Pattern of green-cured material aligned to green absorber in multicolor mask
34 Pattern of second transparent functional material
36 Third transparent functional material
38 Red-curable layer
40 Pattern of red-curable material aligned to red absorber in multicolor mask
42 Pattern of third transparent functional material aligned to red absorber in multicolor mask
44 Pan-curable layer
46 Pan-curable layer that has been cured
48 Transparent functional material

1. A process for forming a stacked transparent structure comprising providing a support, coating one side of said support with a multicolored mask, coating the other side of the support with a layer curable by visible light, and exposing the light-curable layer through the mask with visible light to cure the layer curable by light in exposed portions to form a cured pattern.

2. The process of claim 1 wherein the area not cured by the visible light is removed.

3. The process of claim 1 wherein the light utilized for curing has a light spectrum matching one of the colors of the multicolored mask.

4. The process of claim 1 wherein the exposing light is white light and the layer curable by visible light is only curable by a light spectrum matching one color of the multicolored mask.

5. The process of claim 1 wherein light utilized for curing has a light spectrum matching one of the colors of the multicolored mask and the visible light utilized for exposure also has the same color.

6. The process of claim 1 wherein said multicolored mask comprises a multicolor layer formed by photographic replication of a master color image onto said support.

7. The process of claim 1 wherein said multicolored mask is laminated onto said support after preforming onto a substrate.

8. The process of claim 1 wherein said multicolored mask comprises at least two colors selected from magenta, cyan and yellow.

9. The process of claim 1 wherein said multicolored mask is directly printed onto said support.

10. The process of claim 1 wherein said support comprises glass.

11. The process of claim 1 wherein said support comprises a flexible polymer sheet.

12. The process of claim 1 wherein the layer curable by visible light comprises a material sensitive to a single color.

13. The process of claim 12 wherein the layer curable by visible light contains an initiator system for ethylenic addition containing as a photoinitiator a dye capable of absorbing imaging radiation to achieve an excited state only within a specific color (wavelength) range.

14. The process of claim 1 wherein in further steps the support on the side opposite to said multicolored mask is coated with a material curable by ultraviolet light, and said material is exposed through a ultraviolet masking layer.

15. The process of claim 1 wherein said material curable by visible light contains at least one addition polymerizable ethylenically unsaturated compound selected from the group consisting of monomers, oligomers, or crosslinkable polymers and mixtures thereof, and having a boiling point above 100 degrees C. at normal pressure.

16. The process of claim 1 further comprising applying on the side of the support opposite to said multicolored mask a layer of functional transparent material.

17. The process of claim 16 wherein said functional layer is applied to said support prior to application of the material curable by visible light.

18. The process of claim 16 wherein said functional layer is applied after curing of the material cured by visible light and after removable of material not cured.

19. The process of claim 18 further comprising the step of removing the cured material to leave an opening in the functional material.

20. The process of claim 16 wherein said functional material comprises dielectric material.

21. The process of claim 16 wherein said functional material comprises conductive material.

22. The process of claim 16 wherein said functional material comprises semiconductive material.

23. The process of claim 19 further comprising coating at least one more layer curable by visible light onto the previously cured pattern and exposing said at least one more layer curable by visible light to form at least one further cured pattern in register with the first pattern.

24. An article comprising a transparent support, a multicolored mask on the back of the support and at least one patterned layer on the front of the support in register with at least one color of the multicolored mask.

25. The article of claim 24 wherein at least one patterned layer is conductive.

26. The article of claim 24 wherein at least one patterned layer is dielectric.

27. The article of claim 24 wherein at least one patterned layer is semiconductive.

28. The article of claim 24 wherein said at least one pattern comprises a layer comprising material curable by visible light of a color that passes through said multicolored mask.

29. The article of claim 24 wherein said article comprises on the front side in order a patterned conductive layer and a patterned dielectric layer.

30. The article of claim 24 wherein said article comprises on the front side in order a patterned conductive layer, a patterned dielectric layer, a patterned semiconductive layer, and a patterned conductive layer.

31. The article of claim 24 wherein said article comprises on the front side in order a patterned conductive layer, a patterned dielectric layer, a patterned conductive layer, and a patterned semiconductive layer.

32. The article of claim 24 wherein all layers on the front are transparent.

33. The article of claim 24 wherein the front layer furthest from the support is not transparent.

34. The article of claim 24 wherein said patterned layer comprises a dielectric material selected from a group consisting of aluminum oxide, silicon oxide, silicon nitrides and mixtures thereof.

35. The article of claim 24 wherein said patterned layer comprises a conductive material selected from the group consisting of transparent conductors such as indium-tin oxide (ITO), ZnO, SnO₂, or In₂O₃, metals, degenerately doped semiconductors, conducting polymers, and printable conducting materials such as carbon ink, silver-epoxy, or sinterable metal nanoparticle suspensions, and mixtures thereof.

36. The article of claim 24 wherein said patterned layer comprises a semiconductive material selected from the group consisting of zinc oxide, tin oxide and mixtures thereof.

37. The article of claim 24 wherein said article comprises a transistor.

38. An article comprising a support having an imaging layer on the back side of the support and in order from the support a functional transparent layer and a layer curable by visible light on the front side of the support.

39. The article of claim 38 wherein said imaging layer comprises a photographic layer.

40. The article of claim 38 wherein said imaging layer comprises a dye receiving layer.

41. An article comprising a support having an imaging layer on the back side of the support and on the front side has at least one layer of a material that is cured by a visible light whose spectrum matches only a portion of the visible light spectrum.

42. The article of claim 38 wherein said imaging layer comprises a photographic layer.

43. The article of claim 38 wherein said imaging layer comprises a dye receiving layer.

44. The process of claim 1 wherein the mask is on the same side of said support as the layer curable by visible light.

45. The process of claim 1 wherein the mask is on the opposite side of said support from the layer curable by visible light.
